(19) United States
(12) Patent Application Publication
(10) Pub. No.: US 2026/0265118 A1
(43) Pub. Date: Sep. 10, 2026

(54) CHEMICALLY STRENGTHENED GLASS, COVER GLASS, DISPLAY, AND SOLAR CELL MODULE

(71) Applicant: AGC Inc., Tokyo (JP)

(72) Inventor: Kaname SEKIYA, Tokyo (JP)

(73) Assignee: AGC Inc., Tokyo (JP)

(21) Appl. No.: 19/663,520

(22) Filed: Apr. 30, 2026

Related U.S. Application Data
(63) Continuation of application No. PCT/JP2024/042577, filed on Dec. 2, 2024.

(30) Foreign Application Priority Data
Dec. 6, 2023 (JP) 2023-206400

(51) Int. Cl. C03C 3/097; H05K 5/03; H10F 19/80

(52) U.S. Cl. CPC C03C 3/097; H05K 5/03; H10F 19/804; C03C 2201/10; C03C 2201/28; C03C 2201/32; C03C 2201/3411; C03C 2201/42; C03C 2201/50; C03C 2201/54

(57) ABSTRACT

Provided is chemically strengthened glass with high fracture strength. The chemically strengthened glass has: a thickness of 0.6 mm or less; a surface compressive stress of 600 MPa or greater; a depth of compressive stress layer of 0 to 175 μm; and a value of X, expressed by the following formula (1), being greater than or equal to 0.

$$X = 2.05 \times {E}_{m}^{0.5} + {CS}_{120} \qquad ( 1 )$$

In the formula (1), Eₘ is a Young's modulus at an in-plane center position of the chemically strengthened glass, in units of GPa; and CS₁₂₀ is a compressive stress at a depth of 120 μm in the chemically strengthened glass, in units of MPa.

### TECHNICAL FIELD

The present invention relates to a chemically strengthened glass.

The present invention further relates to a cover glass including the chemically strengthened glass.

The present invention also relates to a display and a solar cell module each including the cover glass.

### BACKGROUND ART

In recent years, cover glasses have been used for protection and appearance improvement of display devices in mobile phones, smartphones, tablet terminals and the like. For these applications, the cover glasses are required to have high strength to suppress breakage due to impacts or the like.

Such cover glasses may also be used for protection of solar cell modules and the like.

Conventionally, a technique is known for improving the surface strength of glass by chemically strengthening the glass through immersion in a molten salt such as potassium nitrate. For example, Patent Document 1 discloses that the surface strength of sheet glass can be improved by chemically strengthening the glass through immersion in a molten salt such as potassium nitrate. More specifically, this patent document discloses production of sheet glass with improved strength by chemical strengthening treatment of Li-containing glass with a Na-containing molten salt and then with a K-containing molten salt. This patent document also discloses that the mechanism for strengthening sheet glass through such chemical treatment is due to compressive stress caused by exchange of alkali metals.

### PRIOR ART DOCUMENTS

### Patent Documents

Patent Document 1: WO2022/004808

### DISCLOSURE OF INVENTION

### Technical Problem

In recent years, cover glasses have sometimes been required to have a reduced thickness in view of weight reduction, improvement in visibility, increase in transmittance, and the like.

The present inventors have studied chemically strengthened glass with reduced thickness (for example, 0.6 mm or less) and have found that the fracture strength of such glass may decrease and thus needs to be increased.

The present invention has been made in light of the above-described problems. It is an object of the present invention to provide a chemically strengthened glass with high fracture strength.

It is also an object of the present invention to provide a cover glass.

Furthermore, it is an object of the present invention to provide a display and a solar cell module.

### Solution to Problem

As a result of intensive studies on the above-described problems, the present inventors have found that the fracture strength of chemically strengthened glass can be increased by adjusting a surface compressive stress, a depth of compressive stress layer and a parameter related to a Young's modulus and the magnitude of compressive stress at a predetermined depth, and thus have accomplished the present invention.

Namely, the present inventors have found the following solutions to the above-described problems.
[1]A chemically strengthened glass having:
   a thickness of 0.6 mm or less;
   a surface compressive stress of 600 MPa or greater;
   a depth of compressive stress layer of 10 to 175 μm; and
   a value of X, expressed by the following formula (1), being greater than or equal to 0:

$$X = 2.05 \times {E}_{m}^{0.5} + {CS}_{120} \qquad ( 1 )$$

where:
Eₘ is a Young's modulus at an in-plane center position of the chemically strengthened glass, in units of GPa; and
CS₁₂₀ is a compressive stress at a depth of 120 μm in the chemically strengthened glass, in units of MPa.
[2] The chemically strengthened glass according to [1], wherein the Young's modulus at the in-plane center position of the chemically strengthened glass is 80 GPa or higher.
[3] The chemically strengthened glass according to [1] or [2], wherein a fracture toughness value K_{IC} at the in-plane center position of the chemically strengthened glass is 0.80 MPa·m^{1/2} or greater.
[4] The chemically strengthened glass according to any one of [1] to [3], wherein no fracture occurs when one surface of the chemically strengthened glass is brought into contact with an abrasive surface of #80 sandpaper comprising silicon carbide as an abrasive, and an impact with an energy of 0.03 J is applied from the side opposite to the abrasive surface of the sandpaper.
[5] The chemically strengthened glass according to any one of [1] to [4], having a composition at a thickness center position thereof, comprising, in mole percentage on an oxide basis:
   60 to 70% of SiO₂;
   10 to 20% of Al₂O₃;
   3 to 12% of Li₂O;
   1 to 5% of Na₂O;
   0 to 3% of K₂O;
   0 to 10% of MgO;
   0 to 10% of CaO;
   0 to 5% of SrO;
   0 to 5% of ZnO;
   0 to 3% of TiO₂;
   0 to 3% of ZrO₂;
   0 to 1% of SnO₂;
   0 to 1% of P₂O₅;
   to 10% of B₂O₃; and
   0 to 3% of Y₂O₃,
   wherein:
   a sum R of the contents of Li₂O, Na₂O and K₂O is 5 to 20%;
   a ratio of the content of Li₂O to R is 0.5 to 0.8; and
   a product of the ratios of the contents of Li₂O, Na₂O and K₂O to R is 0.003 to 0.03.
[6] The chemically strengthened glass according to [5], wherein a Young's modulus at the thickness center position of the chemically strengthened glass is 85 GPa or higher.
[7] The chemically strengthened glass according to any one of [1] to [4], having a composition at a thickness center position thereof, comprising, in mole percentage on an oxide basis:
   55 to 75% of SiO₂;
   3 to 18% of Al₂O₃;
   17 to 30% of Li₂O;
   0 to 3% of Na₂O;
   0 to 1% of K₂O;
   0 to 10% of MgO;
   0 to 10% of CaO;
   0 to 5% of SrO;
   0 to 5% of ZnO;
   0 to 3% of TiO₂;
   0 to 3% of ZrO₂;
   0 to 1% of SnO₂;
   0 to 3% of P₂O₅;
   0 to 10% of B₂O₃;
   0 to 3% of Y₂O₃,
   wherein:
   a sum of the contents of Li₂O, Na₂O and K₂O is 8 to 35%;
   a ratio of the content of Li₂O to R is 0.85 to 0.99; and
   a product of the ratios of the contents of Li₂O, Na₂O and K₂O to R is 0 to 0.003.
[8] The chemically strengthened glass according to [7], wherein a Young's modulus at the thickness center position of the chemically strengthened glass is 90 GPa or higher.
[9]A cover glass comprising the chemically strengthened glass according to any one of [1] to [8].
[10]A display comprising the cover glass according to [9].
[11]A solar cell module comprising the cover glass according to [9].

### Advantageous Effects of Invention

According to the present invention, it is possible to provide a chemically strengthened glass with high fracture strength.

According to the present invention, it is also possible to provide a cover glass.

According to the present invention, it is further possible to provide a display and a solar cell module.

### BRIEF DESCRIPTION OF DRAWINGS

FIG. 1 is a diagram illustrating a method for determining various characteristic temperatures from a DSC curve of glass.

FIG. 2 is a schematic view illustrating a sample used for measuring a fracture toughness value K_{IC} by the DCDC method.

FIG. 3 is a diagram illustrating a K1-v curve, which represents the relationship between a stress intensity factor K1 (unit: MPa·m^{1/2}) and a crack propagation rate v (unit: m/s), used for measuring a fracture toughness value K_{IC} by the DCDC method.

FIG. 4 is a schematic view illustrating a test apparatus used in one embodiment of damage-introducing step in an impact resistance test and a pre-damaged 4PB strength test.

FIG. 5 is a plot diagram illustrating the correlation between an impact energy and a maximum crack depth in the impact resistance test.

### DESCRIPTION OF EMBODIMENTS

Hereinafter, the chemically strengthened glass of the present invention will be described in detail. It should, however, be understood that: the present invention is not limited to the following embodiments; and various changes and modifications can be made to the following embodiments without departing from the scope of the present invention.

In the present specification, a “chemically strengthened glass” refers to a glass having been subjected to chemical strengthening treatment; and a “glass for chemical strengthening” refers to a glass before being subjected to chemical strengthening treatment.

In the present specification, a composition of a glass for chemical strengthening may also be referred to as a base glass composition of a chemically strengthened glass. Since a chemically strengthened glass generally has a compressive stress layer formed by ion exchange in its surface region, a glass composition of the non-ion-exchanged region corresponds to the base glass composition of the chemically strengthened glass.

In the present specification, a glass composition is expressed in mole percentage on an oxide basis, and mol % may be simply referred to as %. Furthermore, a numerical range expressed using “to” indicates a range including numerical values described before and after “to” as the lower and upper limits.

In a glass composition, “substantially free of” means that a component is not contained except as an unavoidable impurity in the raw materials or the like, that is, it is not intentionally contained. More specifically, the content of any component other than those described as the glass composition is, for example, preferably less than 0.1 mol %, more preferably 0.08 mol % or less, still more preferably 0.05 mol % or less.

In the present specification, a “stress profile” refers to a pattern representing compressive stress values as a function of depth from the glass surface. A negative compressive stress value indicates tensile stress.

In the present specification, a “stress profile” can be measured using an optical waveguide surface stress meter and a scattered light photoelastic stress meter in combination.

The optical waveguide surface stress meter can measure stress in a glass accurately in a short time. As an example of the optical waveguide surface stress meter, FSM-6000 manufactured by Orihara Industrial Co., Ltd. may be mentioned. In principle, however, the optical waveguide surface stress meter can measure stress only when the refractive index decreases from the sample surface toward the inside. In a chemically strengthened glass, a layer formed by exchanging sodium ions inside the glass with external potassium ions has a refractive index that decreases from the sample surface toward the inside. Stress in such a layer can be thus measured using the optical waveguide surface stress meter. However, stress in a layer formed by exchanging lithium ions inside the glass with external sodium ions cannot be accurately measured using the optical waveguide surface stress meter.

The scattered light photoelastic stress meter can measure stress regardless of the refractive index distribution. As an example of the scattered light photoelastic stress meter, SLP-1000 manufactured by Orihara Industrial Co., Ltd. may be mentioned. However, the scattered light photoelastic stress meter is susceptible to surface scattering and may not be able to accurately measure stress near the sample surface.

For the above reasons, accurate stress measurement can be achieved by the combined use of two types of measurement devices, namely, the optical waveguide surface stress meter and the scattered light photoelastic stress meter.

In the present specification, a “depth of compressive stress layer” refers to a depth at which the compressive stress value becomes zero.

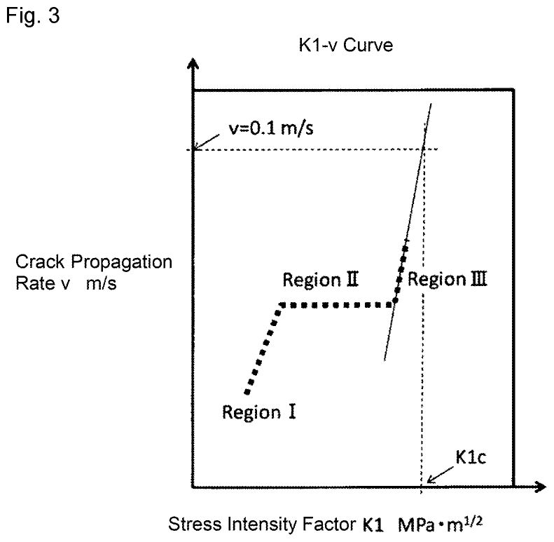

In the present specification, a “fracture toughness value K_{IC}” is measured with reference to the DCDC method (see, for reference, M. Y. He, M. R. Turner and A. G. Evans, Acta Metall. Mater. 43 (1995) 3453). More specifically, using a sample having a shape shown in FIG. 2 and a SHIMADZU Autograph AGS-X5KN, a K1-v curve representing the relationship between a stress intensity factor K1 (unit: MPa·m¹²) and a crack propagation rate v (unit: m/s), as shown in FIG. 3, is obtained. Linear regression is performed on the obtained Region III data, and the resulting linear expression is extrapolated to determine the stress intensity factor K1 at v=0.1 m/s, which is taken as the fracture toughness value K_{IC}.

### <Chemically Strengthened Glass>

The chemically strengthened glass of the present invention has a thickness of 0.6 mm or less, a surface compressive stress of 600 MPa or greater, a depth of compressive stress layer of 10 to 175 μm and a value of X, expressed by the formula (1) described below, being greater than or equal to 0.

The chemically strengthened glass of the present invention, which satisfies the above requirements, exhibits increased fracture strength. The mechanism for such increased fracture strength is not fully understood, but is presumed as follows by the present inventors.

Since the chemically strengthened glass of the present invention has the above-described predetermined surface compressive stress and depth of compressive stress layer, the surface of the chemically strengthened glass is less susceptible to scratches.

Furthermore, the chemically strengthened glass of the present invention has a value of X, expressed by the formula (1), being greater than or equal to 0. As can be understood from the formula (1), the value of X is a parameter related to the Young's modulus at an in-plane center position and the compressive stress at a depth of 120 μm.

It is herein assumed that scratches occur and reach a deep region of the chemically strengthened glass (for example, a depth of 120 μm or more). In this case, a portion of the glass at that depth, having the corresponding composition, is subjected to the stress at that depth. Depending on the balance between the Young's modulus and the stress at that depth, a crack may spontaneously propagate, potentially leading to fracture of the chemically strengthened glass. Through intensive studies, the present inventors have found that: there is a significant correlation between the value of X and the fracture strength; and the fracture strength can be increased by adjusting the value of X to the predetermined value or greater.

Hereinafter, the conditions satisfied by the chemically strengthened glass of the present invention will be described in detail.

### [Thickness]

The thickness of the chemically strengthened glass of the present invention is 0.6 mm or less.

The lower limit of the thickness of the chemically strengthened glass of the present invention is often 0.1 mm or more, and is preferably 0.2 mm or more, more preferably 0.3 mm or more, and still more preferably 0.4 mm or more.

### [Compressive Stress]

The surface compressive stress (CS₀) of the chemically strengthened glass of the present invention is 600 MPa or greater.

In other words, the chemically strengthened glass of the present invention has a compressive stress layer in its surface region.

The compressive stress CS₀ of the chemically strengthened glass of the present invention is preferably 700 MPa or greater, more preferably 750 MPa or greater. The upper limit of the compressive stress CS₀ of the chemically strengthened glass of the present invention is preferably 1500 MPa or less, more preferably 1200 MPa or less, from the viewpoint of facilitating adjustment of the value of X within the predetermined range.

In the present invention, the compressive stress CS₀ of the chemically strengthened glass is measured with the optical waveguide surface stress meter described above.

The compressive stress (CS₃₀) at a depth of 30 μm in the chemically strengthened glass of the present invention is preferably at least −20 MPa, more preferably at least 50 MPa, still more preferably at least 100 MPa, from the viewpoint of making the chemically strengthened glass less susceptible to fracture even under greater impact caused by collision with another object. Further, the compressive stress CS₃₀ is often 500 MPa or less, and is preferably 300 MPa or less, more preferably 200 MPa or less, from the viewpoint of facilitating adjustment of the value of X, expressed by the formula (1), within the predetermined range.

The compressive stress (CS₅₀) at a depth of 50 μm in the chemically strengthened glass of the present invention is preferably −20 MPa or greater, more preferably 50 MPa or greater, still more preferably 100 MPa or greater, from the viewpoint of making the chemically strengthened glass less susceptible to fracture even under great impact caused by collision with another object. The compressive stress CS₅₀ is often 300 MPa or less, and is preferably 200 MPa or less, more preferably 170 MPa or less, from the viewpoint of facilitating adjustment of the value of X, expressed by the formula (1), within the predetermined range.

The compressive stress S₉₀) at a depth of 90 μm in the chemically strengthened glass of the present invention is preferably −20 MPa or greater, more preferably 10 MPa or greater, still more preferably 20 MPa or greater, from the viewpoint of making the chemically strengthened glass less susceptible to fracture even under greater impact caused by collision with another object. The compressive stress CS₉₀ is often 200 MPa or less, and is preferably 100 MPa or less, more preferably 60 MPa or less, from the viewpoint of facilitating adjustment of the value of X, expressed by the formula (1), within the predetermined range.

The compressive stress at each of the above depths can be determined from a stress profile obtained by the method described above.

Each of the above compressive stress values can, for example, be adjusted depending on the conditions of the chemical strengthening treatment described below.

### [Depth of Compressive Stress Layer]

The depth of compressive stress layer in the chemically strengthened glass of the present invention is 10 to 175 μm.

From the viewpoint of achieving higher fracture strength, the depth of compressive stress layer is preferably 150 μm or less, more preferably 120 μm or less. The depth of compressive stress layer is preferably 20 μm or more, more preferably 50 μm or more, still more preferably 70 μm or more, from the viewpoint of making the chemically strengthened glass less susceptible to fracture even under greater impact caused by collision with another object.

The depth of compressive stress layer can, for example, be adjusted depending on the conditions of the chemical strengthening treatment described below.

### [Tensile Stress]

Since the chemically strengthened glass of the present invention has a compressive stress layer in its surface region as described above, tensile stress acts inside the chemically strengthened glass to balance such compressive stress.

The maximum tensile stress (CT_{Max}) in the chemically strengthened glass of the present invention is preferably 200 MPa or less, more preferably 150 MPa or less, still more preferably 130 MPa or less, from the viewpoint of reducing the scattering of glass fragments even upon fracture of the glass. The lower limit of the tensile stress CT_{Max} is not particularly limited, but is often at least 10 MPa.

The tensile stress CT_{Max} can be determined from a stress profile. In general, the tensile stress CT_{Max} acts at a thickness center position.

The average tensile stress (CTₐᵥₑ) in the chemically strengthened glass of the present invention is preferably 200 MPa or less, more preferably 150 MPa or less, still more preferably 100 MPa or less, from the viewpoint of reducing the scattering of glass fragments in the event of fracture of the glass. The lower limit of the average tensile stress CTₐᵥₑ is not particularly limited, but is often 10 MPa or greater.

The average tensile stress can be determined by integrating the tensile stress in the depth direction over a region of depth corresponding to the tensile stress in the stress profile and dividing the integration result by the length of the tensile stress region.

The integrated value (ICT) of the tensile stress in the chemically strengthened glass of the present invention is often 50000 Pa-m or less, and is preferably 40000 Pa-m or less, more preferably 30000 Pa-m or less. The lower limit of the integrated value ICT is not particularly limited, but is often 10000 Pa-m or greater.

The integrated value ICT can be determined by integrating the tensile stress over a region of depth corresponding to the tensile stress in the stress profile.

### [Formula (1)]

For the chemically strengthened glass of the present invention, the value of X, as expressed by the following formula (1), is greater than or equal to 0.

$$X = 2.05 \times {E}_{m}^{0.5} + {CS}_{120} \qquad ( 1 )$$

In the formula (1), Eₘ is the Young's modulus at an in-plane center position of the chemically strengthened glass. The unit of Eₘ is GPa. Here, “Eₘ⁰⁵” represents Eₘ to the power of 0.5 (the square root of Eₘ).

In the formula (1), CS₁₂₀ is the compressive stress at a depth of 120 μm in the chemically strengthened glass. The unit of CS₁₂₀ is MPa. When the compressive stress at a depth of 120 μm is a negative value (tensile stress), the negative value is used in the calculation.

For the chemically strengthened glass of the present invention, the value of X is greater than or equal to 0. From the viewpoint of achieving higher fracture strength, the value of X is preferably 0.2 or greater, more preferably 0.3 or greater. The value of X may be 1.0 or greater, may be 2.0 or greater, or may be 4.0 or greater. The upper limit of the value of X is not particularly limited, and is often 50 or less, preferably 30 or less, more preferably 20 or less.

The compressive stress value CS₁₂₀ in the formula (1) is not particularly limited as long as the value of X falls within the predetermined range. The compressive stress value CS₁₂₀ is preferably −50 MPa or greater, more preferably −30 MPa or greater, still more preferably −20 MPa or greater. The upper limit of the compressive stress value CS₁₂₀ is not particularly limited but is, for example, 50 MPa or less, preferably 30 MPa or less, more preferably 20 MPa or less.

The compressive stress value CS₁₂₀ in the formula (1) can, for example, be adjusted depending on the conditions of the chemical strengthening treatment described below.

### [Young's Modulus]

The Young's modulus (Eₘ) at the in-plane center position of the chemically strengthened glass of the present invention is preferably 80 GPa or higher. The Young's modulus is more preferably 83 GPa or higher, still more preferably 85 GPa or higher, particularly preferably 90 GPa. Here, the Young's modulus at the in-plane center position of a chemically strengthened glass refers to the Young's modulus as measured at the center position in the in-plane direction of a sheet-shaped chemically strengthened glass. The center position in the in-plane direction refers to the center-of-gravity position in the in-plane direction. In the case where the chemically strengthened glass has a square shape, the center position in the in-plane direction corresponds to an intersection point of the diagonals.

The Young's modulus can be adjusted depending on not only the composition (base glass composition) of glass (glass for chemical strengthening) used for production of the chemically strengthened glass, but also the heat treatment conditions such as heat treatment temperature, heat treatment time and cooling rate of the glass for chemical strengthening. For example, in the case where the base glass composition is of a crystallizable type, the Young's modulus can be easily changed depending on the heat treatment conditions.

Furthermore, the Young's modulus at the thickness center position of the chemically strengthened glass of the present invention is preferably 80 GPa or greater, more preferably 83 GPa or greater, still more preferably 85 GPa or greater, particularly preferably 90 GPa or greater. The Young's modulus of the glass for chemical strengthening corresponds to the Young's modulus at the thickness center position of the chemically strengthened glass.

In the present specification, both the Young's modulus at the in-plane center position of the chemically strengthened glass and the Young's modulus at the thickness center position of the chemically strengthened glass can be measured by the ultrasonic pulse method. The detailed method for measuring the Young's modulus is in accordance with the method described in the Examples below.

### [Fracture Toughness Value]

From the viewpoint of achieving higher fracture strength, the fracture toughness value (K_{IC}) at the thickness center position of the chemically strengthened glass of the present invention is preferably 0.75 MPa·m^{1/2} or greater, more preferably 0.80 MPa·m^{1/2} or greater, still more preferably 0.85 MPa·m^{1/2} or greater. The fracture toughness value K_{IC} is often 2.00 MPa·m^{1/2} or less, and is preferably 1.80 MPa·m^{1/2} or less.

The method for measuring the fracture toughness value at the thickness center position of the chemically strengthened glass is in accordance with that described in the Examples below.

Here, the fracture toughness value of the glass for chemical strengthening corresponds to the fracture toughness value at the thickness center position of the chemically strengthened glass.

For example, the fracture toughness value K_{IC} can be measured by the same method as the Young's modulus.

### [Impact Resistance Test]

It is preferable that the chemically strengthened glass of the present invention does not fracture when subjected to the following impact resistance test.

In the impact resistance test, one surface of the chemically strengthened glass is brought into contact with an abrasive surface of #80 sandpaper using silicon carbide as the abrasive, and an impact with an energy of 0.03 J is applied from the side opposite to the abrasive surface of the sandpaper. The occurrence of fracture is then checked.

For the detailed test procedure, reference should be made to the method described in the Example below.

### [Composition]

The chemically strengthened glass of the present invention is obtained by performing chemical strengthening treatment on sheet glass to be chemically strengthened (glass for chemical strengthening).

The preferred composition (base glass composition) of the glass for chemical strengthening will be described below. Here, the base glass composition corresponds to the composition of the chemically strengthened glass at the thickness center position.

In the following, preferred examples of the base glass composition will be described as first and second embodiments.

### First Embodiment

The base glass composition of the first embodiment includes, in mole percentage on an oxide basis:
60 to 72% of SiO₂;
10 to 20% of Al₂O₃;
3 to 12% of Li₂O;
0.5 to 5% of Na₂O;
0 to 3% of K₂O;
0 to 10% of MgO;
0 to 10% of CaO;
0 to 5% of SrO;
0 to 5% of ZnO;
0 to 3% of TiO₂;
0 to 3% of ZrO₂;
0 to 1% of SnO₂;
0 to 1% of P₂O₅;
0 to 10% of B₂O₃; and
0 to 3% of Y₂O₃,
wherein: the sum R of the contents of Li₂O, Na₂O and K₂O is 5 to 20%; the ratio of the content of Li₂O to R is 0.5 to 0.95; and the product of the ratios of the contents of Li₂O, Na₂O and K₂O to R is 0.001 to 0.03.

The respective components of the base glass composition will be described in more detail below. Hereinafter, the content of SiO₂ in mole percentage on an oxide basis may occasionally be referred to as “[SiO₂]”; and the same applies to the other components.

SiO₂ is a component for forming a network structure in the glass. SiO₂ is also a component for improving the chemical durability of the glass and suppressing cracks caused by scratches on the glass surface.

From the viewpoint of improving chemical durability, the content of SiO₂ is preferably 60.0% or more, more preferably 62.0% or more, particularly preferably 64.0% or more, most preferably 66.0% or more. On the other hand, from the viewpoint of achieving good meltability, the content of SiO₂ is preferably 70.0% or less, more preferably 68.0% or less, particularly preferably 67.0% or less, most preferably 66.0% or less.

Al₂O₃ is a component for improving the ion-exchange performance of the glass during chemical strengthening and increasing the surface compressive stress of the glass after chemical strengthening.

From the viewpoint of achieving the above effects, the content of Al₂O₃ is preferably 10.0% or more, more preferably in the following order: 11.0% or more, 11.5% or more, and 12.0% or more. On the other hand, it may be required that: crystals are difficult to grow during melting of the glass; devitrification defects are less likely to occur in the glass, facilitating an improved yield; or the glass is lower in high-temperature viscosity and is easier to melt. In view of such requirements, the content of Al₂O₃ is preferably 15.0% or less, more preferably in the following order: 14.0% or less, 13.5% or less, and 13.0% or less.

Both SiO₂ and Al₂O₃ act to stabilize the structure of the glass. From the viewpoint of reducing glass brittleness, the total content of SiO₂ and Al₂O₃ is preferably 74.0% or more, more preferably 76.0% or more, still more preferably 78.0% or more.

Furthermore, both SiO₂ and Al₂O₃ tend to increase the melting temperature of the glass. From the viewpoint of facilitating melting of the glass, the total content of SiO₂ and Al₂O₃ is preferably 83.0% or less, more preferably 82.0% or less, still more preferably 81.0% or less, particularly preferably 80.5% or less.

Li₂O is a component capable of ion exchange and for improving the meltability of the glass. When Li₂O is contained in the glass, Li ions on the glass surface are exchanged with external Na ions to introduce Na ions into the glass, and the introduced Na ions are exchanged with external K ions. By this method, a stress profile with a high surface compressive stress and a thick compressive stress layer can be easily obtained. From the viewpoint of easily obtaining a favorable stress profile, the content of Li₂O is more preferably 8.0% or more, still more preferably in the following order: 9.0% or more, 9.5% or more, 10.0% or more, 10.2% or more, and 10.4% or more.

On the other hand, from the viewpoint of lowering the rate of crystal growth during glass forming and suppressing quality deterioration caused by devitrification, the content of Li₂O is more preferably 11.8% or less, still more preferably in the following order: 11.5% or less, and 11.0% or less.

Na₂O and K₂O are components for improving the meltability of the glass and lowering the rate of crystal growth during glass forming. From the viewpoint of not only achieving these effects but also improving the ion-exchange performance of the glass, Na₂O and K₂O are preferably contained in small amounts.

Na₂O is a component capable of ion exchange during chemical strengthening treatment with a potassium salt, and is also a component for lowering the viscosity of the glass. From the viewpoint of achieving the above effects, the content of Na₂O is preferably 1% or more, more preferably in the following order: 1.5% or more, 2.5% or more, 3.0% or more, and 4.0% or more.

K₂O is a component for suppressing an increase in devitrification temperature, thereby suppressing devitrification, and for improving the ion-exchange performance of the glass. The content of K₂O is more preferably 0.1% or more, still more preferably 0.15% or more, particularly preferably 0.2% or more, most preferably 0.5% or more.

The sum of the contents of Li₂O, Na₂O and K₂O, referred to as R, is preferably 8% or more, more preferably 9% or more, from the viewpoint of suppressing an increase in devitrification temperature and lowering the rate of crystal growth.

From the viewpoint of further improving chemical strengthening characteristics with respect to the compressive stress in the deep layer region of the glass, the ratio of the content of Li₂O to R ([Li₂O]/([Li₂O]+[Na₂O]+[K₂O]); hereinafter also referred to as “Li₂O/R₂O”) is preferably 0.52 or higher, more preferably 0.55 or higher. The ratio Li₂O/R₂O is preferably 0.90 or lower, more preferably 0.85 or lower, particularly preferably 0.75 or lower, from the viewpoint of achieving higher chemical resistance.

The ratio of the content of Na₂O to R ([Na₂O]/([Li₂O]+[Na₂O]+[K₂O]); hereinafter also referred to as “Na₂O/R₂O”) is preferably higher than 0.08 or higher, more preferably 0.15 or higher, still more preferably 0.20 or higher, from the viewpoint of further improving chemical strengthening characteristics with respect to the compressive stress in the deep layer region of the glass. The ratio Na₂O/R₂O is preferably 0.60 or lower, more preferably 0.50 or lower, still more preferably 0.40 or lower, particularly preferably 0.30 or lower, from the viewpoint of achieving higher chemical resistance.

The ratio of the content of K₂O to R ([K₂O]/([Li₂O]+[Na₂O]+[K₂O]); hereinafter also referred to as “K₂O/R₂O”) is preferably 0.01 or higher, more preferably 0.015 or higher, still more preferably 0.02 or higher, particularly preferably 0.08 or higher, most preferably 0.10 or higher, from the viewpoint of achieving higher glass electrical resistance. From the viewpoint of further improving chemical strengthening characteristics with respect to the compressive stress near the glass surface, the ratio K₂O/R₂O is preferably 0.50 or lower, more preferably 0.40 or lower, still more preferably 0.30 or lower, particularly preferably 0.20 or lower.

The product of the ratios Li₂O/R₂O, Na₂O/R₂O and K₂O/R₂O is preferably 0.002 or higher, more preferably 0.01 or higher, particularly preferably 0.02 or higher, from the viewpoint of suppressing an increase in devitrification temperature. From the viewpoint of improving chemical resistance, the above product is preferably 0.028 or lower.

The ratio of the content of Al₂O₃ to R ([Al₂O₃]/([Li₂O]+[Na₂O]+[K₂O]); hereinafter also referred to as “Al₂O₃/R₂O”) is preferably 0.20 or higher, more preferably 0.30 or higher, still more preferably 0.40 or higher, particularly preferably 0.50 or higher. The ratio Al₂O₃/R₂O is preferably 1.50 or lower, more preferably 0.80 or lower, still more preferably 0.75 or lower, particularly preferably 0.70 or lower, most preferably 0.65 or lower.

The ratio of the content of K₂O to the content of Na₂O (hereinafter also referred to as “[K₂O]/[Na₂O]”) is preferably 0.0 to 1.8. From the viewpoint of increasing the compressive stress near the glass surface and readily obtaining the chemically strengthened glass with higher bending strength, the ratio [K₂O]/[Na₂O] is more preferably 0.1 or higher, still more preferably 0.2 or higher, yet more preferably 0.4 or higher, particularly preferably 0.5 or higher. In view of the above points, the ratio [K₂O]/[Na₂O] is more preferably 1.0 or lower, still more preferably 0.9 or lower, yet more preferably 0.8 or lower, particularly preferably 0.7 or lower.

The value expressed by [Al₂O₃]—[Na₂O]—[K₂O]+[Li₂O] is preferably 10.0 to 22.0%, more preferably 10.0 to 20.0%, still more preferably 12.0 to 18.0%.

MgO may be contained to lower the viscosity of the glass during melting or for other purposes. The content of MgO is more preferably 0.05% or more, still more preferably in the following order: 0.1% or more, 0.2% or more, 0.9% or more, more than 0.9%, and 1.0% or more.

On the other hand, from the viewpoint of easily forming a thicker compressive stress layer during chemical strengthening treatment, the content of MgO is more preferably 8.0% or less, still more preferably in the following order: 7.5% or less, 5.0% or less, 4.0% or less, 3.8% or less, 3.0% or less, 2.0% or less, and 1.5% or less. When the content of MgO is 4.0% or less, acid resistance can be improved.

Furthermore, by containing MgO, it is possible to suppress the crystal phase transition from β-quartz solid solution to β-spodumene and suppress the precipitation of β-spodumene crystals. It is thus preferable in the first embodiment to contain MgO. From the above viewpoint, MgO is preferably contained in an amount of more than 0.5% and 7.0% or less. The further preferred ranges are as described above.

CaO is a component for improving the meltability of the glass and may be contained. The content of CaO is more preferably 0.1% or more, still more preferably 0.15% or more. On the other hand, from the viewpoint of easily achieving a greater compressive stress value during chemical strengthening treatment, the content of CaO is more preferably 2.0% or less, still more preferably 1.0% or less, particularly preferably 0.8% or less, most preferably 0.5% or less.

From the viewpoint of achieving higher glass stability, it is preferable to contain at least one of MgO and CaO, and it is more preferable to contain MgO. The total content of MgO and CaO is preferably more than 0.1%, more preferably 0.2% or more, still more preferably 0.5% or more. From the viewpoint of further improving chemical strengthening characteristics, the total content of MgO and CaO is preferably 10.0% or less, more preferably in the following order: 5.0% or less, 3.0% or less, 2.0% or less, and 1.0% or less.

SrO is a component for improving the meltability of the glass and may be contained. The content of SrO is preferably 0.1% or more, still more preferably 0.15% or more, particularly preferably 0.5% or more.

From the viewpoint of easily achieving a greater compressive stress value during chemical strengthening treatment, the content of SrO is more preferably 3.0% or less, still more preferably 2.0% or less, particularly preferably 1.0% or less, most preferably 0.5% or less.

The glass may be substantially free of SrO.

BaO is a component for improving the meltability of the glass and may be contained. When BaO is contained, the content of BaO is preferably 0.1% or more, more preferably 0.15% or more, still more preferably 0.5% or more.

From the viewpoint of easily achieving a greater compressive stress value during chemical strengthening treatment, the content of BaO is preferably 3.0% or less, more preferably 2.0% or less, still more preferably 1.0% or less, particularly preferably 0.5% or less.

The glass may be substantially free of BaO.

ZnO is a component for improving the meltability of the glass. The content of ZnO is more preferably 0.1% or more, still more preferably 0.15% or more, particularly preferably 0.5% or more.

From the viewpoint of easily achieving a greater compressive stress value during chemical strengthening treatment, the content of ZnO is more preferably 3.0% or less, still more preferably 2.0% or less, particularly preferably 1.0% or less, most preferably 0.5% or less.

The glass may be substantially free of ZnO.

InW is a parameter representing the degree of mixing of oxides, as calculated from the contents of alkali metal oxides, alkaline earth metal oxides and zinc oxide. Here, InW is expressed by the following formula.

$$InW = ln ( ( [ {Li}_{2} O ] + [ {Na}_{2} O ] + [ {K}_{2} O ] + [ MgO ] + [ CaO ] + [ SrO ] + [ BaO ] + [ ZnO ] ) ! \text{} / ( [ {Li}_{2} O ] ! \times [ {Na}_{2} O ] ! \times [ {K}_{2} O ] ! \times [ MgO ] ! \times [ CaO ] ! \times [ SrO ] ! \times [ BaO ] ! \times [ ZnO ] ! ) ) \qquad ( W1 )$$

In the formula (W1), [Li₂O], [Na₂O], [K₂O], [MgO], [CaO], [SrO], [BaO] and [ZnO] represent the contents of Li₂O, Na₂O, K₂O, MgO, CaO, SrO, BaO and ZnO, respectively, in mole percentage on an oxide basis.

Furthermore, ! represents the factorial of a positive integer. For example, [XO]! means that the numerical value of the content of a component XO, in mole percentage on an oxide basis, is rounded down to the nearest integer, and then, the factorial of the resulting integer is calculated. When the Na₂O content is, for example, 4.8 mol %, [Na₂O]! means calculating the factorial of “4”, i.e., 4×3×2×1.

The greater the value of InW, the higher the degree of mixing of the metal oxides, and accordingly, devitrification of the glass can be suppressed. From the above viewpoints, the value of InW is preferably 10 or greater, more preferably 12 or greater, still more preferably 13 or greater, particularly preferably 14 or greater. The value of InW is preferably 20 or less, more preferably 18 or less, still more preferably 17 or less.

TiO₂ is a component highly effective in suppressing solarization of glass, and may be contained. When TiO₂ is contained, the content of TiO₂ is preferably 0.02% or more, more preferably 0.03% or more, still more preferably 0.04% or more, particularly preferably 0.05% or more, most preferably 0.06% or more.

On the other hand, from the viewpoint of preventing quality deterioration of the chemically strengthened glass due to devitrification, the content of TiO₂ is preferably 2.0% or less, more preferably 1.0% or less, still more preferably 0.5% or less, particularly preferably 0.25% or less, most preferably 0.15% or less.

ZrO₂ is a component for easily increasing the surface compressive stress of the chemically strengthened glass. The content of ZrO₂ is more preferably more than 0%, still more preferably in the following order: 0.1% or more, 0.15% or more, 0.2% or more, 0.25% or more, 0.3% or more, and 0.4% or more.

On the other hand, from the viewpoint of suppressing devitrification defects and easily achieving a greater compressive stress value during chemical strengthening treatment, the content of ZrO₂ is more preferably 2.0% or less, still more preferably 1.5% or less, particularly preferably 1.0% or less, most preferably 0.6% or less.

P₂O₅ is a component for easily forming a thicker compressive stress layer during chemical strengthening. The content of P₂O₅ is more preferably 0.5% or more, still more preferably 1.0% or more, particularly preferably 2.0% or more.

On the other hand, from the viewpoint of achieving higher acid resistance, the content of P₂O₅ is more preferably 4.0% or less, still more preferably 2.0% or more. From the viewpoint of preventing the occurrence of striae during glass melting, it is also preferable that the glass is substantially free of P₂O₅.

B₂O₃ is a component for reducing the brittleness of the glass and improving the crack resistance of the glass, and/or for improving the meltability of the glass. The content of B₂O₃ is more preferably 0.5% or more, more preferably 1.0% or more, still more preferably 2.0% or more.

On the other hand, the content of B₂O₃ is preferably 8.0% or less from the viewpoint of maintaining good acid resistance. The content of B₂O₃ is more preferably 6.0% or less, still more preferably 4.0% or less, particularly preferably 2.0% or less. From the viewpoint of preventing the occurrence of striae during glass melting, it is also preferable that the glass is substantially free of B₂O₃.

Y₂O₃ is a component for lowering the rate of crystal growth while easily increasing the surface compressive stress of the chemically strengthened glass. The content of Y₂O₃ is more preferably more than 0%, still more preferably in the following order: 0.1% or more, 0.2% or more, 0.5% or more, and 1.0% or more.

On the other hand, the content of Y₂O₃ is more preferably 2.0% or less from the viewpoint of easily forming a thicker compressive stress layer during chemical strengthening treatment.

From the viewpoint of improving initial solubility, the total content of ZrO₂ and Y₂O₃ is preferably 4.0% or less, more preferably 2.4% or less. The lower limit of the total content of ZrO₂ and Y₂O₃ is not particularly limited, but is preferably 0.5% or more, more preferably in the following order: 0.7% or more, 1.0% or more, and 1.2% or more, from the viewpoint of increasing the strength of the glass.

The ratio of the content of ZrO₂ to the total content of ZrO₂ and Y₂O₃, referred to as [ZrO₂]/([ZrO₂]+[Y₂O₃]), is preferably 0.10 or higher, more preferably 0.20 or higher, particularly preferably 0.25 or higher. The ratio [ZrO₂]/([ZrO₂]+[Y₂O₃]) is preferably 0.60 or lower, more preferably 0.50 or lower, particularly preferably 0.45 or lower, most preferably 0.40 or lower.

Although ZrO₂ and Y₂O₃ are known to act as nucleating agents when added individually, the co-addition of ZrO₂ and Y₂O₃ enables control of the devitrification temperature, crystal growth rate and crystallization start temperature through the formation of a eutectic of ZrO₂ and Y₂O₃.

Further, by controlling the ratio [ZrO₂]/([ZrO₂]+[Y₂O₃]) to within the above-described range, ion diffusion in the glass can be suppressed, thereby limiting an increase in devitrification temperature and suppressing devitrification.

By controlling the [ZrO₂]/([ZrO₂]+[Y₂O₃]) to within the above-described range, the glass can be stabilized, and the nucleation and crystal growth temperature regions can be separated without overlap, thereby suppressing an increase in crystal growth rate. As a result, the occurrence of defects can be suppressed. Moreover, by controlling the [ZrO₂]/([ZrO₂]+[Y₂O₃]) to within the above-described range, the nucleation temperature region shifts to a low temperature side, thereby suppressing a decrease in crystallization start temperature and improving production characteristics.

From the viewpoint of reducing defects in the glass, the value expressed by 100×[ZrO₂]+63×[Y₂O₃] is preferably 250 or less, more preferably 180 or less, still more preferably 175 or less, yet more preferably 170 or less, particularly preferably 165 or less, most preferably 160 or less.

The lower limit of the value expressed by 100×[ZrO₂]+63×[Y₂O₃] is not particularly limited, but is preferably 100 or greater, more preferably 110 or greater, still more preferably 125 or greater, particularly preferably 130 or greater, from the viewpoint of promoting nucleation.

La₂O₃ is not an essential component, but may be contained for the same reasons as Y₂O₃. The content of La₂O₃ is preferably 0.1% or more, more preferably 0.2% or more, still more preferably 0.5% or more, particularly preferably 0.8% or more. Since excessive La₂O₃ makes it difficult to form a thicker compressive stress layer during chemical strengthening treatment, the content of La₂O₃ is preferably 5.0% or less, more preferably 3.0% or less, still more preferably 2.0% or less, particularly preferably 1.5% or less.

It is also preferable that the glass is substantially free of La₂O₃.

Nb₂O₅, Ta₂O₅, Gd₂O₃ and CeO₂ are components effective in suppressing solarization of glass and in improving the meltability of glass, and thus may be contained. When Nb₂O₅, Ta₂O₅, Gd₂O₃ and CeO₂ are contained, the content of each of these components is preferably 0.03% or more, more preferably 0.1% or more, still more preferably 0.5% or more, particularly preferably 0.8% or more, most preferably 1.0% or more. On the other hand, the content of each of these components is preferably 3.0% or less, more preferably 2.0% or less, still more preferably 1.0% or less.

Fe₂O₃ is capable of absorbing heat radiation and thus effective in improving the meltability of the glass. In the mass-production of glass using a large melting furnace, it is preferable to contain Fe₂O₃. In such a case, the content of Fe₂O₃ in mass % on an oxide basis is preferably 0.002% or more, more preferably 0.005% or more, still more preferably 0.007% or more, particularly preferably 0.01% or more. On the other hand, excessive Fe₂O₃ results in coloring of the glass. From the viewpoint of enhancing the transparency of the glass, the content of Fe₂O₃ in mass % on an oxide basis is preferably 0.3% or less, more preferably 0.04% or less, still more preferably 0.025% or less, particularly preferably 0.015% or less.

Other coloring components may be added within the range that does not inhibit the desired chemical strengthening characteristics. Suitable examples of such coloring components include Co₃O₄, MnO₂, NiO, CuO, Cr₂O₃, V₂O₅, Bi₂O₃, SeO₂, Er₂O₃ and Nd₂O₃.

SO₃, a chloride, a fluoride or the like may be appropriately contained as a fining agent during glass melting. It is preferable that As₂O₃ is not contained. When Sb₂O₃ is contained, the content of Sb₂O₃ is preferably 0.3% or less, more preferably 0.1% or less. Most preferably, Sb₂O₃ is not contained.

From the viewpoint of refining bubbles in the glass, the content of SnO₂ is preferably 0.1% or more, more preferably 0.2% or more, particularly preferably 0.3% or more. From the viewpoint of reducing defects in the glass, the content of SnO₂ is preferably 1% or less, more preferably 0.8% or less, still more preferably 0.7% or less, particularly preferably 0.5% or less.

The preferable physical properties of the glass having the base glass composition of the first embodiment will next be described below.

### (Devitrification Temperature)

In the glass for chemical strengthening having the base glass composition of the first embodiment, the devitrification temperature is preferably 1300° C. or lower. The devitrification temperature is more preferably 1280° C. or lower, still more preferably 1250° C. or lower, particularly preferably in the following order: 1240° C. or lower, 1230° C. or lower, 1220° C. or lower, and 1210° C. or lower. The lower limit of the devitrification temperature is not particularly limited, but is usually 1100° C. or higher.

When the devitrification temperature is 1300° C. or lower (preferably 1250° C. or lower), the glass can be formed stably, and production characteristics can be improved. More specifically, for example, in the case where the glass is formed by e.g. the float method, crystals may develop before the pouring of the molten glass into the float bath, potentially causing erosion of the bricks constituting the float bath. Such brick erosion can be suppressed when the glass devitrification temperature is 1300° C. or lower (preferably 1250° C. or lower).

Here, the devitrification temperature of the glass refers to the minimum temperature at which no precipitated crystals on the surface of or inside the glass are observed with an optical microscope after the glass, crushed to a particle size of 2 mm to 3 mm, is placed in a platinum dish and heat-treated for 17 hours in an electric furnace maintained at a constant temperature.

### (Glass Transition Temperature Tg, Crystallization Start Temperature Tcs and Crystallization Peak Temperature Tc)

In the present specification, the differential scanning calorimetry (DSC) measurement of the glass is conducted by grinding the glass in an agate mortar to obtain a glass powder with a particle size of 106 to 180 μm, and then, heating about 70 mg of the glass powder from room temperature to 1200° C. at a heating rate of 10° C./min.

In the glass for chemical strengthening having the base glass composition of the first embodiment, the crystallization start temperature Tcs as measured by DSC is preferably 790° C. or higher, more preferably 800° C. or higher, still more preferably 810° C. or higher, yet more preferably 815° C. or higher, particularly preferably 820° C. or higher, most preferably 825° C. or higher. The upper limit of the crystallization start temperature is not particularly limited, but is usually 900° C. or lower.

When the crystallization start temperature Tcs is 790° C. or higher, production characteristics can be improved. More specifically, in the case where the glass is first formed into a sheet shape and then formed into a three-dimensional shape through heat treatment (for example, 2.5D or 3D forming; hereinafter also referred to as three-dimensional forming), the glass passes through its nucleation temperature during heating from room temperature to the forming temperature so that defects are likely to occur due to crystallization. When the crystallization start temperature Tcs is 790° C. or higher, the glass can be formed without passing through the nucleation temperature during heating from room temperature to the forming temperature, thereby suppressing the occurrence of defects.

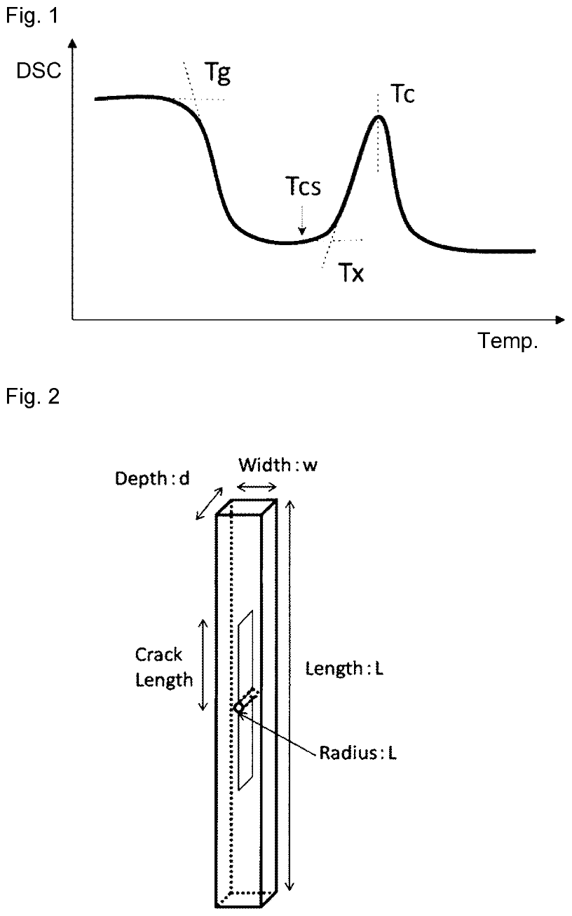

FIG. 1 is a schematic diagram for explaining Tg, Tcs and Tc in the present specification. As shown in FIG. 1, the glass transition temperature Tg is determined as the intersection of auxiliary lines drawn on the DSC curve, and the crystallization start temperature Tcs is determined as the exothermic peak temperature of the DSC curve during heating of the glass at 10° C./min.

In the glass for chemical strengthening having the base glass composition of the first embodiment, the ratio of the crystallization start temperature Tcs to the glass transition temperature Tg, as expressed by (Tcs+273.15)/(Tg+273.15), is preferably 1.10 or higher, more preferably 1.15 or higher, still more preferably 1.20 or higher, particularly preferably 1.25 or higher. By controlling the ratio (Tcs+273.15)/(Tg+273.15) to 1.10 or higher, the occurrence of defects during three-dimensional forming can be suppressed, and the forming properties can be improved. The upper limit of the ratio (Tcs+273.15)/(Tg+273.15) is not particularly limited, but is usually 1.6 or lower in view of the glass formability. In the ratio (Tcs+273.15)/(Tg+273.15), Tcs and Tg are in units of ° C. The value of “(Tcs+273.15)/(Tg+273.15)” corresponds to the value of “Tcs/Tg” where both temperatures are expressed in units of K.

In the glass for chemical strengthening having the base glass composition of the first embodiment, the value (Tcs−Tg) obtained by subtracting the glass transition temperature Tg from the crystallization start temperature Tcs is preferably 180° C. or more, more preferably 200° C. or more, still more preferably 210° C. or more, yet more preferably 215° C. or more, particularly preferably 225° C. or more, most preferably 230° C. or more. When the value (Tcs−Tg) is 200° C. or more, the occurrence of defects during three-dimensional forming can be suppressed, and the forming properties can be improved. The upper limit of the value (Tcs−Tg) is not particularly limited, but is usually preferably 400° C. or less in view of the glass formability.

In the glass for chemical strengthening having the base glass composition of the first embodiment, the value (Tcs−Tg) obtained by subtracting the glass transition temperature Tg from the crystallization start temperature Tcs is preferably 180° C. or more, more preferably 185° C. or more.

The glass transition temperature Tg is preferably 500° C. or higher, more preferably 520° C. or higher, still more preferably 540° C. or higher, from the viewpoint of reducing warpage of the glass after chemical strengthening. From the viewpoint of facilitating float forming of the glass, the glass transition temperature Tg is preferably 750° C. or lower, more preferably 700° C. or lower, still more preferably 650° C. or lower, particularly preferably 600° C. or lower, most preferably 580° C. or lower.

In the glass for chemical strengthening having the base glass composition of the first embodiment, the crystallization peak temperature Tc is preferably 790° C. or higher, more preferably 800° C. or higher, still more preferably 810° C. or higher. When the crystallization peak temperature Tc is 790° C. or higher, the glass can be formed stably. It is most preferable that no crystallization peak is observed. The upper limit of the crystallization peak temperature Tc is not particularly limited, and is usually 950° C. or lower.

### (Crystal Growth Rate)

By containing MgO in the glass for chemical strengthening having the base glass composition of the first embodiment, it is possible to suppress the crystal phase transition from β-quartz solid solution to β-spodumene and suppress the precipitation of β-spodumene crystals. Accordingly, the precipitation of β-spodumene can be suppressed even when the glass for chemical strengthening is held at 1000° C. for 30 minutes. Furthermore, the rate of crystal growth can also be lowered.

In the case where MgO is contained in the glass for chemical strengthening having the base glass composition of the first embodiment, the first precipitated phase is preferably β-quartz solid solution; and the crystal growth rate of the β-quartz solid solution at 1000° C. is preferably 4000 μm/hr or lower, more preferably 3800 μm/hr or lower, still more preferably 3500 μm/hr or lower, particularly preferably 3200 μm/hr or lower, most preferably 2700 μm/hr or lower.

In the glass forming process, crystallization in the glass causes defects. For example, in the case where the glass is formed by the float method, crystallization occurs in part of the float bath where the nucleation and crystal growth temperature regions overlap, as the glass is cooled from the high-temperature zone.

In ordinary glass, the nucleation and crystal growth temperature regions do not overlap. In contrast, in glass with high Al₂O₃ and Li₂O contents, the nucleation and crystal growth temperature regions tend to overlap at or around 1000° C. The overlap between the nucleation and crystal growth temperature regions would not necessarily constitute a drawback when the crystal growth rate is low. Therefore, crystallization during the forming process can be suppressed by controlling the crystal growth rate of the β-quartz solid solution at 1000° C. to 600 μm/hr or lower.

In the present specification, the crystal growth rate of β-quartz solid solution at 1000° C. is determined by holding a glass sample at 1000° C. for 30 minutes, measuring the lengths of crystals in the glass sample with a polarized optical microscope and calculating the average of the measured crystal lengths. The crystal growth rate of the β-spodumene at 1000° C. is determined by the same method as above.

The “13-OH value” is determined by the following formula (1):

$$β - OH value = ( 1 / t ) {log}_{10} ( {X}_{1} / {X}_{2} ) \qquad ( 1 )$$

where X₁ is the transmittance (%) of the glass as measured by the FT-IR method at a reference wavelength of 4000 cm⁻¹; X₂ is the minimum transmittance (%) of the glass as measured by the FT-IR method at a wavelength near 3570 cm⁻¹, which corresponds to an absorption wavelength of hydroxyl groups; and t is the thickness (unit: mm) of the glass.

The β-OH value can be adjusted according to the water content and melting conditions of raw glass materials.

In the glass for chemical strengthening having the base glass composition of the first embodiment, the β-OH value is preferably 0.1 mm⁻¹ or greater, more preferably 0.15 mm⁻¹ or greater, still more preferably 0.2 mm⁻¹ or greater, particularly preferably 0.22 mm⁻¹ or greater, most preferably 0.25 mm⁻¹ or greater.

The β-OH value is an index of the water content in the glass. Glass with a higher β-OH value exhibits a lower softening point and tends to be easier to bend. On the other hand, in strength improvement of glass by chemical strengthening, the surface compressive stress (CS) of the glass after chemical strengthening tends to decrease as the β—OH value of the glass increases. In view of the above points, the β-OH value is preferably 0.5 mm⁻¹ or less, more preferably 0.4 mm⁻¹ or less, still more preferably 0.3 mm⁻¹ or less.

In a preferable embodiment described below, a first-stage chemical strengthening is performed using a Na salt, followed by a second-stage chemical strengthening using a mixed Li/K salt, thereby introducing K into the glass. In the glass for chemical strengthening having the base glass composition of the first embodiment, from the viewpoint of readily improving the drop strength of the glass during such chemical strengthening, the ratio of Na_DOL to K_DOL, as defined below (hereinafter also referred to as “Na_DOL/K_DOL”), is preferably 26 or lower, more preferably in the following order: 25 or lower, 24 or lower, 23 or lower, 22 or lower, 21 or lower, and 20 or lower.

From the viewpoint of preventing excessive introduction of K into the glass during the second-stage chemical strengthening using a mixed Li/K salt after the first-stage chemical strengthening using a Na salt, thereby preventing breakage of the glass, the ratio Na_DOL/K_DOL is preferably 15 or higher, more preferably in the following order: 16 or higher, 16.5 or higher, 17 or higher, 17.5 or higher, and 18 or higher.
K_DOL: Depth of compressive stress layer in glass chemically strengthened by ion-exchange treatment with a molten salt of 100% potassium nitrate
Na_DOL: Depth of compressive stress layer in glass chemically strengthened by ion-exchange treatment with a molten salt of 100% sodium nitrate

Here, the time and temperature conditions of the ion-exchange treatments for determination of K_DOL and Na_DOL are the same conditions.

In the glass for chemical strengthening having the base glass composition of the first embodiment, the fracture toughness value (K_{IC}) is preferably 0.80 MPa·m^{1/2} or greater, more preferably 0.810 MPa·m^{1/2} or greater, still more preferably 0.82 MPa·m^{1/2} or greater, particularly preferably 0.83 MPa·m^{1/2} or greater, most preferably 0.84 MPa·m^{1/2} or greater. The upper limit of the fracture toughness value is not particularly limited, but is typically 1.0 MPa·m^{1/2} or less.

In the glass for chemical strengthening having the base glass composition of the first embodiment, the Young's modulus is preferably 80 GPa or higher, more preferably 85 GPa or higher, still more preferably 90 GPa or higher, particularly preferably 95 GPa or higher. The upper limit of the Young's modulus is not particularly limited, but is typically 120 GPa or lower.

### Second Embodiment

The base glass composition of the second embodiment includes, in mole percentage on an oxide basis:
55 to 75% of SiO₂;
3 to 18% of Al₂O₃;
17 to 30% of Li₂O;
0 to 3% of Na₂O;
0 to 1% of K₂O;
0 to 10% of MgO;
0 to 10% of CaO;
0 to 5% of SrO;
0 to 5% of ZnO;
0 to 3% of TiO₂;
0 to 3% of ZrO₂;
0 to 1% of SnO₂;
0 to 3% of P₂O₅;
0 to 10% of B₂O₃; and
0 to 3% of Y₂O₃,
wherein: the sum R of the contents of Li₂O, Na₂O and K₂O is 8 to 35%; the ratio of the content of Li₂O to R is 0.85 to 0.99; and the product of the ratios of the contents of Li₂O, Na₂O and K₂O to R is 0 to 0.003.

The respective components of this base glass composition will be described in more detail below.

SiO₂ is a component for forming a network structure in the glass. SiO₂ is also a component for improving the chemical resistance of the glass and suppressing cracks caused by scratches on the glass surface.

From the viewpoint of improving chemical resistance, the content of SiO₂ is more preferably 57.0% or more, still more preferably 58.0% or more, particularly preferably 59.0% or more, most preferably 60.0% or more. On the other hand, from the viewpoint of achieving good meltability, the content of SiO₂ is more preferably 74.0% or less, still more preferably 72.0% or less, particularly preferably 69.0% or less, most preferably 66.0% or less.

Al₂O₃ is a component for improving the ion-exchange performance of the glass during chemical strengthening and increasing the surface compressive stress of the glass after chemical strengthening. In addition, Al₂O₃ contributes to the formation of crystals containing Al and Li.

From the viewpoint of achieving the above effects, the content of Al₂O₃ is more preferably 3.5% or more, still more preferably in the following order: 4.0% or more, and 4.5% or more. On the other hand, it may be required that: crystals are difficult to grow during melting of the glass; devitrification defects are less likely to occur in the glass, facilitating an improved yield; or the glass is lower in high-temperature viscosity and is easier to melt. In view of such requirements, the content of Al₂O₃ is more preferably 18.0% or less, still more preferably in the following order: 15.0% or less, 12.0% or less, 9.0% or less, 7.0% or less, and 6.0% or less.

Both SiO₂ and Al₂O₃ act to stabilize the structure of the glass. From the viewpoint of reducing glass brittleness, the total content of SiO₂ and Al₂O₃ is preferably 60.0% or more, more preferably 62.0% or more, still more preferably 64.0% or more.

Furthermore, both SiO₂ and Al₂O₃ tend to increase the melting temperature of the glass. From the viewpoint of facilitating melting of the glass, the total content of SiO₂ and Al₂O₃ is preferably 80.0% or less, more preferably 75.0% or less, still more preferably 70.0% or less, particularly preferably 68.0% or less.

Li₂O is a component capable of ion exchange and for improving the meltability of the glass. When Li₂O is contained in the glass, Li ions on the glass surface are exchanged with external Na ions to introduce the Na ions into the glass, and the introduced Na ions are exchanged with external K ions. By this method, a stress profile with a high surface compressive stress and a thick compressive stress layer can be easily obtained. Furthermore, the glass can be easily obtained in crystallized form by specific heat treatment when the content of Li₂O falls within the above-described range. In view of the above points, the content of Li₂O is more preferably 17% or more, still more preferably in the following order: 19% or more, 21% or more, and 22% or more.

On the other hand, from the viewpoint of lowering the rate of crystal growth during glass forming and suppressing quality deterioration caused by devitrification, the content of Li₂O is more preferably 30% or less, still more preferably in the following order: 28% or less, 26% or less, 24% or less, and 23% or less.

Na₂O and K₂O are components for improving the meltability of the glass and lowering the rate of crystal growth during glass forming. From the viewpoint of not only achieving these effects but also improving the ion-exchange performance of the glass, Na₂O and K₂O are preferably contained in small amounts.

Na₂O is a component capable of ion exchange during chemical strengthening treatment with a potassium salt, and is also a component for lowering the viscosity of the glass. From the viewpoint of achieving the above effects, the content of Na₂O is more preferably 0.3% or more, still more preferably in the following order: 0.5% or more, 0.8% or more, 1.0% or more, 1.2% or more, 1.5% or more, and 1.8% or more. On the other hand, from the viewpoint of maintaining glass network and avoiding a decrease in surface compressive stress (Na_CS) during strengthening treatment with a sodium salt, the content of Na₂O is preferably 3.0% or less, more preferably 2.5% or less, still more preferably 2.3% or less.

K₂O is a component for suppressing an increase in devitrification temperature, thereby suppressing devitrification, and for improving the ion-exchange performance of the glass. The content of K₂O is more preferably 0.1% or more, still more preferably 0.15% or more, particularly preferably 0.2% or more, most preferably 0.5% or more.

On the other hand, from the viewpoint of avoiding a decrease in surface compressive stress (K_CS) during strengthening treatment with a sodium salt, the content of K₂O is more preferably 1.0% or less, still more preferably 0.8% or less.

The glass may be substantially free of K₂O.

From the viewpoint of suppressing an increase in devitrification temperature and lowering the rate of crystal growth, the sum of the contents of Li₂O, Na₂O and K₂O, referred to as R, is more preferably 10 to 30%, still more preferably 15 to 28%, particularly preferably 18 to 25%.

From the viewpoint of further improving the deep-layer stress in the chemical strengthening characteristics, the ratio of the content of Li₂O to R ([Li₂O]/([Li₂O]+[Na₂O]+[K₂O]); hereinafter also referred to as “Li₂O/R₂O”) is more preferably 0.88 or higher, still more preferably 0.90 or higher. From the viewpoint of achieving higher glass electrical resistance and chemical resistance, the ratio Li₂O/R₂O is preferably 0.98 or lower, more preferably 0.95 or lower, particularly preferably 0.93 or lower.

From the viewpoint of further improving deep-layer stress in the chemical strengthening characteristics, the ratio of the content of Na₂O to R ([Na₂O]/([Li₂O]+[Na₂O]+[K₂O]); hereinafter also referred to as “Na₂O/R₂O”) is preferably higher than 0, more preferably 0.01 or higher, still more preferably 0.03 or higher, particularly preferably 0.05 or higher, most preferably 0.06 or higher. The ratio Na₂O/R₂O is preferably 0.40 or lower, more preferably 0.30 or lower, still more preferably 0.20 or lower, particularly preferably 0.10 or lower, from the viewpoint of achieving higher chemical resistance.

From the viewpoint of achieving higher glass electrical resistance, the ratio of the content of K₂O to R ([K₂O]/([Li₂O]+[Na₂O]+[K₂O]); hereinafter also referred to as “K₂O/R₂O”) is preferably 0.05 or higher, more preferably 0.08 or higher, still more preferably 0.10 or higher. From the viewpoint of further increasing the compressive stress near the glass surface in the chemical strengthening characteristics, the ratio K₂O/R₂O is preferably 0.50 or lower, more preferably 0.40 or lower, still more preferably 0.30 or lower, particularly preferably 0.20 or lower.

The ratio K₂O/R₂O may be zero.

From the viewpoint of suppressing an increase in devitrification temperature and lowering the rate of crystal growth, the product of the ratios Li₂O/R₂O, Na₂O/R₂O and K₂O/R₂O is more preferably 0.008 or higher, still more preferably 0.01 or higher, particularly preferably 0.02 or higher. The above product is more preferably 0.028 or lower.

The above product may be zero.

The ratio of the content of Al₂O₃ to R ([Al₂O₃]/([Li₂O]+[Na₂O]+[K₂O]); hereinafter also referred to as “Al₂O₃/R₂O”) is preferably 0.05 or higher, more preferably 0.10 or higher, still more preferably 0.15 or higher, particularly preferably 0.20 or higher. The ratio Al₂O₃/R₂O is preferably 0.50 or lower, more preferably 0.40 or lower, still more preferably 0.30 or lower, particularly preferably 0.25 or lower.

The value expressed by [Al₂O₃]—[Na₂O]—[K₂O]+[Li₂O] is preferably 15.0 to 35.0%, more preferably 20.0 to 30.0%.

MgO may be contained to lower the viscosity of the glass during melting or for other purposes. The content of MgO is more preferably 0.05% or more, still more preferably in the following order: 0.5% or more, 1.0% or more, 2.0% or more, 3.0% or more, and 4.0% or more.

On the other hand, from the viewpoint of easily forming a thicker compressive stress layer during chemical strengthening treatment, the content of MgO is more preferably 9.0% or less, still more preferably in the following order: 8.0% or less, 7.0% or less, and 6.0% or less.

Furthermore, by containing MgO, it is possible to suppress the crystal phase transition from β-quartz solid solution to β-spodumene and suppress the precipitation of β-spodumene crystals. It is thus preferable in the second embodiment to contain MgO. From the above viewpoint, MgO is preferably contained in an amount of more than 0.5% and 7.0% or less. The further preferred ranges are as described above.

The glass may be substantially free of MgO.

CaO is a component for improving the meltability of the glass and may be contained. The content of CaO is more preferably 0.1% or more, still more preferably 0.15% or more. On the other hand, from the viewpoint of easily achieving a greater compressive stress value during chemical strengthening treatment, the content of CaO is more preferably 2.0% or less, still more preferably 1.0% or less, particularly preferably 0.8% or less, most preferably 0.5% or less.

The glass may be substantially free of CaO.

From the viewpoint of achieving higher glass stability, it is preferable to contain at least one of MgO and CaO, and it is more preferable to contain MgO. The total content of MgO and CaO is preferably more than 1.0%, more preferably 2.0% or more, still more preferably 3.0% or more, particularly preferably 4.0% or more. From the viewpoint of further improving chemical strengthening characteristics, the total content of MgO and CaO is preferably 10.0% or less, more preferably in the following order: 8.0% or less, 7.0% or less, and 6.0% or less.

SrO is a component for improving the meltability of the glass and may be contained. The content of SrO is more preferably 0.1% or more, still more preferably 0.15% or more, particularly preferably 0.5% or more.

From the viewpoint of easily achieving a greater compressive stress value during chemical strengthening treatment, the content of SrO is more preferably 3.0% or less, still more preferably 2.0% or less, particularly preferably 1.0% or less, most preferably 0.5% or less.

The glass may be substantially free of SrO.

BaO is a component for improving the meltability of the glass and may be contained. When BaO is contained, the content of BaO is preferably 0.1% or more, more preferably 0.15% or more, still more preferably 0.5% or more.

From the viewpoint of easily achieving a greater compressive stress value during chemical strengthening treatment, the content of BaO is preferably 3.0% or less, more preferably 2.0% or less, still more preferably 1.0% or less, particularly preferably 0.5% or less.

The glass may be substantially free of BaO.

ZnO is a component for improving the meltability of the glass. The content of ZnO is more preferably 0.1% or more, still more preferably 0.15% or more, particularly preferably 0.5% or more.

From the viewpoint of easily achieving a greater compressive stress value during chemical strengthening treatment, the content of ZnO is more preferably 3.0% or less, still more preferably 2.0% or less, particularly preferably 1.0% or less, most preferably 0.5% or less.

The glass may be substantially free of ZnO.

InW is a parameter representing the degree of mixing of oxides, as calculated from the contents of alkali metal oxides, alkaline earth metal oxides and zinc oxide. Here, InW is expressed by the following formula.

$$InW = ln ( ( [ {Li}_{2} O ] + [ {Na}_{2} O ] + [ {K}_{2} O ] + [ MgO ] + [ CaO ] + [ SrO ] + [ BaO ] + [ ZnO ] ) ! \text{} / ( [ {Li}_{2} O ] ! \times [ {Na}_{2} O ] ! \times [ {K}_{2} O ] ! \times [ MgO ] ! \times [ CaO ] ! \times [ SrO ] ! \times [ BaO ] ! \times [ ZnO ] ! ) ) \qquad ( W1 )$$

$$In the formula ( W 1 ) , [ \text{} {Li}_{2} \text{} O ] , [ \text{} {Na}_{2} \text{} O ] , [ \text{} {K}_{2} \text{} O ] , [ \text{} MgO ] , [ \text{} CaO ] , [ \text{} SrO ] , [ BaO ] and [ ZnO ]$$

represent the contents of Li₂O, Na₂O, K₂O, MgO, CaO, SrO, BaO and ZnO, respectively, in mole percentage on an oxide basis.

Furthermore, ! represents the factorial of a positive integer. For example, [XO]! means that the numerical value of the content of a component XO, in mole percentage on an oxide basis, is rounded down to the nearest integer, and then, the factorial of the resulting integer is calculated. When the Na₂O content is, for example, 4.8 mol %, [Na₂O]! means calculating the factorial of “4”, i.e., 4×3×2×1.

The greater the value of InW, the higher the degree of mixing of the metal oxides, and accordingly, devitrification of the glass can be suppressed. From the above viewpoints, the value of InW is preferably 10 or greater, more preferably 12 or greater, still more preferably 13 or greater, particularly preferably 14 or greater. The value of InW is preferably 20 or less, more preferably 18 or less, still more preferably 17 or less.

TiO₂ is a component highly effective in suppressing solarization of glass and is a material for forming crystal nuclei. Thus, TiO₂ may be contained. When TiO₂ is contained, the content of TiO₂ is preferably 0.05% or more, more preferably 0.1% or more, still more preferably 0.2% or more, particularly preferably 0.5% or more, most preferably 0.8% or more.

Since TiO₂ has light-absorbing properties, the content of TiO₂ is preferably 2.5% or less, more preferably 2.0% or less, still more preferably 1.5% or less, particularly preferably 1.0% or less, from the viewpoint of preventing coloring of the glass.

The glass may be substantially free of TiO₂.

ZrO₂ is a component for easily increasing the surface compressive stress of the chemically strengthened glass, and is a material for forming crystal nuclei. Thus, ZrO₂ may be contained. The content of ZrO₂ is more preferably more than 0%, still more preferably in the following order: 0.5% or more, 1.0% or more, 1.5% or more, 2.0% or more, and 2.5% or more.

P₂O₅ is a component for easily forming a thicker compressive stress layer during chemical strengthening. The content of P₂O₅ is more preferably 0.5% or more, still more preferably 1.0% or more, particularly preferably 2.0% or more.

On the other hand, from the viewpoint of achieving higher acid resistance, the content of P₂O₅ is more preferably 2.0% or less. From the viewpoint of preventing the occurrence of striae during glass melting, it is also preferable that the glass is substantially free of P₂O₅.

B₂O₃ is a component for reducing the brittleness of the glass and improving the crack resistance of the glass, and/or for improving the meltability of the glass. The content of B₂O₃ is more preferably 0.5% or more, more preferably 1.0% or more, still more preferably 2.0% or more.

On the other hand, from the viewpoint of maintaining good acid resistance, the content of B₂O₃ is preferably 8.0% or less. The content of B₂O₃ is more preferably 6.0% or less, still more preferably 4.0% or less, particularly preferably 2.0% or less. From the viewpoint of preventing the occurrence of striae during glass melting, it is also preferable that the glass is substantially free of B₂O₃.

Y₂O₃ is a component for lowering the rate of crystal growth while easily increasing the surface compressive stress of the chemically strengthened glass. The content of Y₂O₃ is more preferably more than 0%, still more preferably in the following order: 0.1% or more, 0.2% or more, 0.5% or more, and 0.8% or more. On the other hand, from the viewpoint of easily forming a thicker compressive stress layer during chemical strengthening treatment, the content of Y₂O₃ is more preferably 2.0% or less, still more preferably 1.5% or less.

From the viewpoint of improving initial solubility, the total content of ZrO₂ and Y₂O₃ is preferably 5.0% or less. The lower limit of the total content of ZrO₂ and Y₂O₃ is not particularly limited, but is preferably 0.5% or more, more preferably in the following order: 1.0% or more, 1.5% or more, 2.0% or more, 2.5% or more, and 3.0% or more, from the viewpoint of increasing the strength of the glass.

The ratio of the content of ZrO₂ to the total content of ZrO₂ and Y₂O₃, referred to as [ZrO₂]/([ZrO₂]+[Y₂O₃]), is preferably 0.50 or higher, more preferably 1.00 or higher, particularly preferably 2.00 or higher. The ratio [ZrO₂]/([ZrO₂]+[Y₂O₃]) is preferably 8.00 or lower, more preferably 7.00 or lower, particularly preferably 6.00 or lower.

Although ZrO₂ and Y₂O₃ are known to act as nucleating agents when added individually, the co-addition of ZrO₂ and Y₂O₃ enables control of the devitrification temperature, crystal growth rate and crystallization start temperature through the formation of a eutectic of ZrO₂ and Y₂O₃.

Further, by controlling the ratio [ZrO₂]/([ZrO₂]+[Y₂O₃]) to within the above-described range, ion diffusion in the glass can be suppressed, thereby limiting an increase in devitrification temperature and thereby suppress devitrification.

By controlling the [ZrO₂]/([ZrO₂]+[Y₂O₃]) to within the above-described range, the glass can be stabilized, and the nucleation and crystal growth temperature regions can be separated without overlap, thereby suppressing an increase in crystal growth rate. As a result, the occurrence of defects can be suppressed. Moreover, by controlling the [ZrO₂]/([ZrO₂]+[Y₂O₃]) to within the above-described range, the nucleation temperature region shifts to a low temperature side, thereby suppressing a decrease in crystallization start temperature and improving production characteristics.

La₂O₃ is not an essential component, but may be contained for the same reasons as Y₂O₃. The content of La₂O₃ is preferably 0.1% or more, more preferably 0.2% or more, still more preferably 0.5% or more, particularly preferably 0.8% or more. Since excessive La₂O₃ makes it difficult to form a thicker compressive stress layer during chemical strengthening treatment, the content of La₂O₃ is preferably 5.0% or less, more preferably 3.0% or less, still more preferably 2.0% or less, particularly preferably 1.5% or less.

It is also preferable that the glass is substantially free of La₂O₃.

Nb₂O₅, Ta₂O₅, Gd₂O₃ and CeO₂ are components effective in suppressing solarization of glass and in improving the meltability of the glass, and thus may be contained. When Nb₂O₅, Ta₂O₅, Gd₂O₃ and CeO₂ are contained, the content of each of these components is preferably 0.03% or more, more preferably 0.1% or more, still more preferably 0.5% or more, particularly preferably 0.8% or more, most preferably 1.0% or more. On the other hand, the content of each of these components is preferably 3.0% or less, more preferably 2.0% or less, still more preferably 1.0% or less.

Fe₂O₃ is capable of absorbing heat radiation and thus is effective in improving the meltability of the glass. In the mass-production of glass using a large melting furnace, it is preferable to contain Fe₂O₃. In such a case, the content of Fe₂O₃ in mass % on an oxide basis is preferably 0.002% or more, more preferably 0.005% or more, still more preferably 0.007% or more, particularly preferably 0.01% or more. On the other hand, excessive Fe₂O₃ results in coloring of the glass. From the viewpoint of enhancing the transparency of the glass, the content of Fe₂O₃ in mass % on an oxide basis is preferably 0.3% or less, more preferably 0.04% or less, still more preferably 0.025% or less, particularly preferably 0.015% or less.

Other coloring components may be added within the range that does not inhibit the desired chemical strengthening characteristics. Suitable examples of such coloring components include Co₃O₄, MnO₂, NiO, CuO, Cr₂O₃, V₂O₅, Bi₂O₃, SeO₂, Er₂O₃ and Nd₂O₃.

SO₃, a chloride, a fluoride or the like may be appropriately contained as a fining agent during glass melting. It is preferable that As₂O₃ is not contained. When Sb₂O₃ is contained, the content of Sb₂O₃ is preferably 0.3% or less, more preferably 0.1% or less. Most preferably, Sb₂O₃ is not contained.

From the viewpoint of refining bubbles in the glass, the content of SnO₂ is preferably 0.1% or more, more preferably 0.2% or more, particularly preferably 0.3% or more. From the viewpoint of reducing defects in the glass, the content of SnO₂ is preferably 1% or less, more preferably 0.8% or less, still more preferably 0.7% or less, particularly preferably 0.5% or less.

The preferable physical properties of the glass having the base glass composition of the second embodiment will next be described below.

### (Devitrification Temperature)

Since the preferred range of the devitrification temperature of the glass for chemical strengthening having the base glass composition of the second embodiment is the same as that of the glass for chemical strengthening having the base glass composition of the first embodiment, a description thereof is omitted.

### (Glass Transition Temperature Tg, Crystallization Start Temperature Tcs and Crystallization Peak Temperature Tc)

In the glass for chemical strengthening having the base glass composition of the second embodiment, the crystallization start temperature Tcs as measured by DSC is preferably 500° C. or higher. The upper limit of the crystallization start temperature Tcs is not particularly limited, but is usually 800° C. or lower.

When the crystallization start temperature Tcs falls within the above-described range, the glass for chemical strengthening in crystallized form is obtained by precipitating crystals in the glass through heat treatment of, for example, holding at 500 to 600° C. for 1 to 6 hours, followed by holding at 600 to 800° C. for 0.5 to 6 hours.

The heat treatment may be performed in three steps. For example, the glass for chemical strengthening in crystallized form can be obtained by holding at 500 to 600° C. for 1 to 6 hours, followed by holding at 550 to 650° C. for 0.5 to 6 hours and then holding at 600 to 800° C. for 0.5 to 6 hours.

From the viewpoint of reducing warpage of the glass after chemical strengthening, the glass transition temperature Tg is preferably 500° C. or higher, more preferably 520° C. or higher, still more preferably 540° C. or higher. From the viewpoint of facilitating float forming of the glass, the glass transition temperature Tg is preferably 750° C. or lower, more preferably 700° C. or lower, still more preferably 650° C. or lower, particularly preferably 600° C. or lower, most preferably 580° C. or lower.

In the glass for chemical strengthening having the base glass composition of the second embodiment, the crystallization peak temperature Tc is preferably 600° C. or higher, more preferably 650° C. or higher, still more preferably 700° C. or higher. When the crystallization peak temperature Tc is 600° C. or higher, the glass can be formed stably. It is most preferable that no crystallization peak is observed. The upper limit of the crystallization peak temperature Tc is not particularly limited, but is usually 950° C. or lower.

In the glass for chemical strengthening having the base glass composition of the second embodiment, the β—OH value is preferably 0.1 mm⁻¹ or greater, more preferably 0.15 mm⁻¹ or greater, still more preferably 0.2 mm⁻¹ or greater, particularly preferably 0.22 mm-1 or greater, most preferably 0.25 mm⁻¹ or greater.

The β-OH value is an index of the water content in glass. Glass with a higher β-OH value exhibits a lower softening point and tends to be easier to bend. On the other hand, in strength improvement of glass by chemical strengthening, the surface compressive stress (CS) of the glass after chemical strengthening tends to decrease as the β-OH value of the glass increases. In view of the above points, the β-OH value is preferably 0.5 mm⁻¹ or less, more preferably 0.4 mm⁻¹ or less, still more preferably 0.3 mm⁻¹ or less.

In the glass for chemical strengthening having the base glass composition of the second embodiment, the fracture toughness value (K_{IC}) is preferably 0.80 MPa·m^{1/2} or greater, more preferably 0.85 MPa·m^{1/2} or greater, still more preferably 0.90 MPa·m^{1/2} or greater, particularly preferably 1.0 MPa·m^{1/2} or greater, most preferably 1.1 MPa·m^{1/2} or greater. The upper limit of the fracture toughness value K_{IC} is not particularly limited, but is typically 1.6 MPa·m^{1/2} or lower.

In the glass for chemical strengthening having the base glass composition of the second embodiment, the Young's modulus is preferably 80 GPa or higher, more preferably 90 GPa or higher, still more preferably 95 GPa or higher, most preferably 100 GPa or higher. The upper limit of the Young's modulus is not particularly limited, but is typically 120 GPa or lower.

### (Production Method)

The glass for chemical strengthening (the base glass composition of the first embodiment or the base glass composition of the second embodiment) can be produced by an ordinary method. For example, raw materials for the respective components of the glass are mixed and melted by heating in a glass melting furnace, and the resulting glass is then homogenized by a known method, formed into a desired shape, such as sheet shape, and annealed.

As examples of the method for forming sheet glass, a float method, a press method, a fusion method and a downdraw method may be mentioned. In particular, a float method suitable for mass production is preferred. A continuous forming method other than the float method, such as a fusion method or a downdraw method, is also preferred.

The glass for chemical strengthening having the base glass composition of the second embodiment may be obtained in crystallized form by the heat treatment described above.

Thereafter, the formed sheet glass is processed, as necessary, into a glass substrate etc. by grinding and/or polishing. In the case where the glass substrate is cut into a predetermined shape and size or subjected to chamfering, it is preferable to perform such cutting or chamfering before the chemical strengthening treatment described below so that a compressive stress layer is also formed on end faces of the glass substrate through the subsequent chemical strengthening treatment.

The glass for chemical strengthening may have a shape other than a sheet shape, depending on the product to which it is applied and its intended use. The sheet glass may have a rim with different thicknesses around its perimeter. The sheet glass is not limited to this shape. For example, two main surfaces of the sheet glass may not be parallel to each other, and a part or the whole of one or both two main surfaces of the sheet glass may be curved. More specifically, the sheet glass may be a flat glass sheet with no warpage or may be a curved glass sheet with a curved surface.

### [Chemical Strengthening Treatment]

The chemically strengthened glass of the present invention is produced by performing chemical strengthening treatment on the glass for chemical strengthening (the base glass composition of the first embodiment or the base glass composition of the second embodiment).

The chemical strengthening treatment can be performed by a known method. For example, the chemical strengthening treatment is performed by bringing the sheet-shaped glass into contact with a molten metal salt (such as potassium nitrate) containing metal ions having a large ion radius (typically, K ions). The contact of the sheet-shaped glass with the molten metal salt can be done by, for example, immersing the sheet glass in the molten metal salt.

Upon contact of the sheet-shaped glass with the molten metal salt, metal ions having a smaller ion radius (typically Na ions or Li ions) in the sheet glass are exchanged with metal ions having a larger ion radius (typically K ions for Na ions, Na or K ions for Li ions).

The chemical strengthening treatment, that is, the ion exchange treatment can be carried out, for example, by immersing the sheet-shaped glass in a molten salt of potassium nitrate or the like heated at 360 to 600° C. for 0.1 to 500 hours. The heating temperature of the molten salt is preferably 375° C. or higher and 500° C. or lower. The immersion time of the sheet-shaped glass in the molten salt is preferably 0.3 hours or more and 200 hours or less.

As the metal salt contained in the molten salt for chemical strengthening treatment, a nitrate, a sulfate, a carbonate, a chloride or the like may be exemplified. Examples of the nitrate include lithium nitrate, sodium nitrate, potassium nitrate, cesium nitrate and silver nitrate. Examples of the sulfate include lithium sulfate, sodium sulfate, potassium sulfate, cesium sulfate and silver sulfate. Examples of the carbonate include lithium carbonate, sodium carbonate and potassium carbonate. Examples of the chloride include lithium chloride, sodium chloride, potassium chloride, cesium chloride and silver chloride. These metal salts may be used alone or in combination of two or more thereof.

The stress profile of the glass can be adjusted depending on the treatment conditions of the chemical strengthening treatment. More specifically, CS₁₂₀ in the above-described formula (1) can be controlled.

The treatment conditions of the chemical strengthening treatment include, for example, the type and composition of the molten salt used, the temperature of the molten salt and the contact time with the molten salt, by which the above parameters can be adjusted. Furthermore, the above parameters can also be adjusted depending on the composition of the glass for chemical strengthening.

The chemical strengthening treatment may be performed only once, or may be performed a plurality of times under two or more different conditions (multi-stage strengthening). Although the chemical strengthening treatment may be performed in a single stage, it is preferable to perform the chemical strengthening treatment in two or more stages.

The chemical strengthening treatment is preferably performed by bringing a Li-containing glass for chemical strengthening into contact with a molten metal salt containing at least Na ions (a first molten salt), and then with a molten metal salt containing at least K ions (a second molten salt).

The first molten salt may preferably include a metal salt containing Na ions and a metal salt containing K ions. In the case where the first molten salt includes a metal salt containing Na ions and a metal salt containing K ions, the content of the metal salt containing Na ions relative to the total mass of the first molten salt is preferably 5 mass % or more, more preferably 10 mass % or more, still more preferably 20 mass % or more, particularly preferably 40 mass % or more. The first molten salt may consist solely of a metal salt containing Na ions.

The second molten salt may preferably include a metal salt containing K ions and a metal salt containing Li ions. The second metal salt may further include a metal salt containing Na ions.

### <Uses>

The chemically strengthened glass of the present invention is useful, for example, as cover glasses.

The cover glasses are suitably applicable for surface protection of displays, solar cell modules and the like.

In particular, the chemically strengthened glass of the present invention is useful as cover glasses for mobile devices such as mobile phones, smartphones, personal digital assistants (PDAs) and tablet terminals. The chemically strengthened glass of the present invention is also useful for applications not intended for mobile uses, including cover glasses for display devices in televisions (TVs), personal computers (PCs), in-vehicle display systems, touch panels and the like, cover glasses on surfaces of solar cell modules, walls of elevators, walls (full-screen displays) of houses and buildings, architectural materials such as window glass, table tops, and interior parts of automobiles, aircrafts and the like. The chemically strengthened glass of the present invention is further useful as cover glasses for the above-mentioned articles.

Furthermore, the chemically strengthened glass of the present invention can be applied to casings having curved shapes and the like by bending or forming.

### EXAMPLES

The present invention will now be described in further detail with reference to the following Examples.

The materials, amounts used, proportions, treatment operations, treatment procedures, and the like shown in the following Examples can be modified as appropriate without departing from the spirit of the present invention. Therefore, it should be understood that the scope of the present invention is by no means restricted to the following Examples.

Here, Ex. 4, 5, 7, 8, 10, 11, 17 and 24 correspond to Examples of the present invention; and Ex. 1 to 3, 6, 9, 12 to 16, 18 to 23 and 25 correspond to Comparative Examples.

### <Production of Chemically Strengthened Glasses>

First, glass raw materials were melted in platinum crucibles to prepare glass materials A to C and P having glass compositions in mole percentage on an oxide basis, as shown in Table 1.

More specifically, the glass raw materials were appropriately selected from those commonly used as raw materials, such as oxides, hydroxides, carbonates, nitrates, and the like, and weighed such that the total amount of the glass would be 1000 g.

Subsequently, the resulting raw material mixture was put in a platinum crucible and melted in a resistance heating electric furnace at 1500 to 1700° C. for approximately 3 hours. The melt was deaerated and homogenized to obtain a molten glass. The molten glass was poured into a mold, held at a temperature 50° C. above the glass transition temperature for 1 hour and cooled at a rate of 0.5° C./min to obtain a glass block. The glass block was cut and ground into a glass sheet. Both surfaces of the glass sheet were mirror-polished, thereby finally obtaining sheet glass (glass for chemical strengthening) having dimensions of 120 mm in length×60 mm in width x 0.55 mm in thickness or 120 mm in length×60 mm in width×0.7 mm in thickness.

From the glass block, sample pieces for measuring the fracture toughness value (K_{IC}) and Young's modulus by the above-described methods were cut out.

For the glass material B, the sheet glass, after being obtained, was subjected to heat treatment by heating to 550° C. and holding for 2 hours, followed by heating to 720° C. and holding at 2 hours.

For the glass material P, the sheet glass, after being obtained, was subjected to heat treatment by heating to 540° C. and holding for 4 hours, followed by heating to 600° C., holding for 4 hours, further heating to 710° C. and holding for 4 hours.

Furthermore, for the glass material B, the same heat treatment as above was performed on the glass block to obtain the sample pieces for measuring the fracture toughness value (K_{IC}) and the Young's modulus.

Each of the glasses for chemical strengthening (glass materials A to C and P) obtained by the above procedure was then subjected to chemical strengthening under the conditions shown in Table 2, thereby obtaining chemically strengthened glasses of Ex. 1 to 25.

### <Measurement of Stress Profile>

The stress profile of the chemically strengthened glass was measured by the method described above.

### <Measurement of Young's Modulus>

Using the sample piece cut out during the preparation of each glass material, the Young's modulus of the glass for chemical strengthening was measured. More specifically, the measurement was conducted on the sample piece by the ultrasonic pulse method in accordance with JIS R1602. The Young's modulus of the glass for chemical strengthening corresponds to the Young's modulus at the thickness center position of the chemically strengthened glass.

Further, the Young's modulus at the in-plane center position of the chemically strengthened glass was measured by the same method as that used for the above sample piece, and was found to be the same as that obtained from the above sample piece. Accordingly, the Young's modulus at the in-plane center position of the chemically strengthened glass is omitted in the table below.

### <Measurement of Fracture Toughness Value>

Using the sample piece cut out during the preparation of each glass material, the fracture toughness value of the chemically strengthened glass was measured. The measurement of the fracture toughness value was conducted by the DCDC method described above.

### <Calculated Value>

The value of X was calculated according to the formula (1) described above.

### <Impact Resistance Test>

An impact resistance test was conducted according to the following procedure.

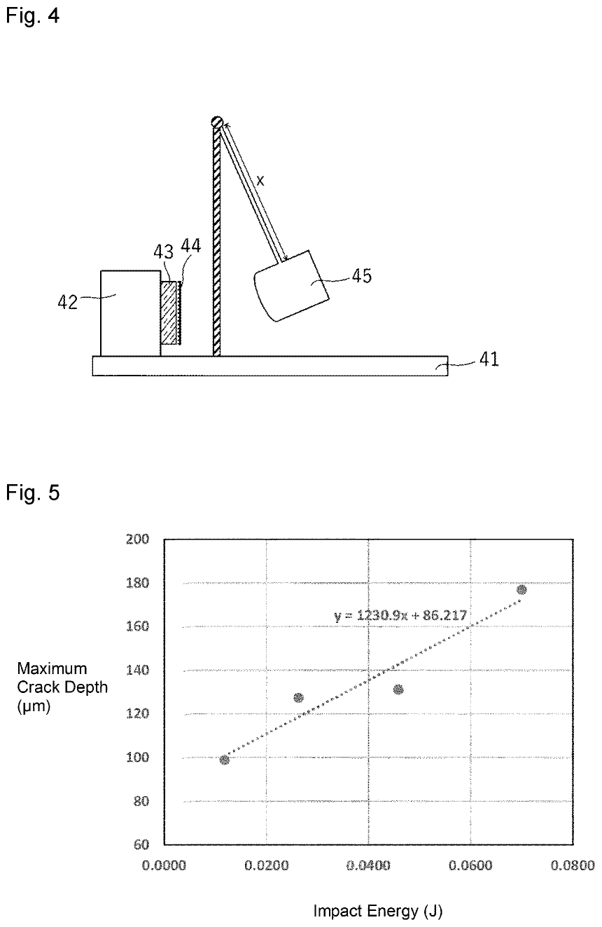

FIG. 4 is a schematic view of a test apparatus used in one embodiment of the impact resistance test.

A glass sample 43 was fixed to one surface of an iron block stand 42 on a stage 41 with adhesive tape. Subsequently, the glass sample 43 and sandpaper 44 were adhered to each other with adhesive tape such that a surface of the glass sample 43 opposite to the fixed surface was in contact with a grit surface (abrasive surface) of the sandpaper 44. The abrasive of the sandpaper 44 was silicon carbide, and the grit size of the sandpaper was #80. The adhesive tape was detachable from the block stand 42, the glass sample 43 and the sandpaper 44. The adhesive tape was attached at a position apart from the collision point of a pendulum 45 as described below.

With the sandpaper 44 and the glass sample 43 fixed to the block stand 42, the pendulum 45 was positioned such that the pendulum at rest was in contact with a surface of the sandpaper 44 opposite to the abrasive surface. The impact surface of the pendulum 45 (the side in contact with the sandpaper 44; the left side of FIG. 4) had a curvature radius of 200 mm, the mass of the pendulum 45 was 50 g, and the length x of the pendulum 45 was 400 mm.

The pendulum 45 was positioned as described above and swung from the side opposite to the abrasive surface of the sandpaper 44 toward the block stand 42, thereby applying an impact to the glass sample 43 by collision with the pendulum. The lifting height of the pendulum 45 was adjusted such that the impact energy was 0.03 J.

After the collision, the glass sample 43 was checked for fracture. Fracture is defined as glass being broken into two or more fragments as a result of propagation of cracks caused by collision.

### <Evaluation>

The average fracture stress was determined according to the following procedure.

Using the apparatus shown in FIG. 4, damage was introduced to a surface of the glass sample 43. More specifically, in the impact resistance test described above, the lifting height of the pendulum 45 was adjusted such that the impact energy was 0.03 J. An impact was applied to the glass sample 43 in the same manner as in the above-described impact resistance test. By this procedure, the surface of the glass sample 43 was damaged, generating small scratches within a surface region of approximately 5 mm in radius around the point where the weight of the pendulum 45 collided via the sandpaper 44.

A bending test was conducted on the glass sample damaged by the above procedure. As the bending test, a four-point bending test (4PB test) was carried out in accordance with JIS R1601:2008. A Shimadzu Autograph AGS-10kNX tabletop precision universal testing machine was used as the four-point bending test apparatus. To evaluate the entire damaged region, the upper and lower spans of the bending test were set to 20 mm and 40 mm, respectively. The moving speed of the crosshead was set to 5 mm/min. The fracture stress was calculated from the load measured at fracture.

The above fracture stress measurement was conducted on five glass samples, and the arithmetic mean of the measured fracture stress values was taken as the average fracture stress.

### Results

For each Ex. the composition of the glass for chemical strengthening and the conditions of the chemical strengthening treatment, together with the measurement and evaluation results, are shown in Tables 1 to 3 below. Tables 2 and 3 are each divided into two parts, referred to as “Part 1” and “Part 2”.

In Table 2, the Young's modulus and K_{IC} (fracture toughness value) represent values measured using the sample pieces by the above-described methods.

Here, the entries in the “Stress Profile” column of Table 3 have the following meanings. The calculation method for each value was as described above or as described below.
K_CS₀: Surface compressive stress of chemically strengthened glass due to potassium ions

The value of “K_CS₀” typically refers to the compressive stress at the outermost surface, measured using an optical waveguide surface stress meter.
K_DOL: Depth of compressive stress layer in chemically strengthened glass due to potassium ions

The value of “K_DOL” typically refers to the depth at which the compressive stress is 0 MPa in the stress distribution measured using only the optical waveguide surface stress meter. When it is difficult to measure “K_DOL” with the optical waveguide surface stress meter, “K_DOL” may be obtained by measuring the distribution of potassium in the thickness direction with an electron probe micro analyzer (EPMA) and determining the diffusion depth of potassium from the measured potassium distribution.
CS₀ to CS₁₂₀: Compressive stress at each depth (unit: μm) in chemically strengthened glass
DOL: Depth of compressive stress layer in chemically strengthened glass
Na_DOL: Depth of compressive stress layer in chemically strengthened glass caused by sodium ions

The value of “Na_DOL” typically refers to the depth at which the compressive is 0 MPa in the stress distribution measured using only a scattered light photoelastic stress meter
CT_{Max}: Maximum tensile stress
CTₐᵥₑ: Average tensile stress
ICT: Integrated value of tensile stress

In the “Impact Resistance Test” column of Table 3, “N” indicates that no fracture occurred when an impact was applied at the above energy value; and “Y” indicates that fracture occurred when an impact was applied at the above energy value.

Furthermore, the value of “X” in the “Calculated Value” column of Table 3 represents a value calculated by the method described above.

TABLE 1

| | Glass Material | A | B | C | P |
|---|---|---|---|---|---|
| Composition (mol %) | SiO₂ | 66 | 61 | 64.3 | 71 |
| | B₂O₃ | 0 | 0 | 0 | 0 |
| | Al₂O₃ | 12 | 5 | 8 | 4.5 |
| | P₂O₅ | 0 | 2 | 0 | 1 |
| | Y₂O₃ | 1.5 | 1 | 0 | 0 |
| | Li₂O | 11 | 21 | 0 | 21 |
| | Na₂O | 5 | 2 | 12.5 | 0.39 |
| | K₂O | 3 | 0 | 4 | 0.1 |
| | MgO | 0.7 | 5 | 11 | 0 |
| | CaO | 0.2 | 0 | 0.1 | 0.01 |
| | SrO | 0 | 0 | 0.1 | 0 |
| | ZnO | 0 | 0 | 0 | 0 |
| | ZrO₂ | 0.5 | 3 | 0 | 2 |
| | TiO₂ | 0.1 | 0 | 0 | 0 |
| | SnO₂ | 0 | 0 | 0 | 0 |
| | Fe₂O₃ | 0 | 0 | 0 | 0 |
| | SUM | 100 | 100 | 100 | 100 |

| | | | | |
|---|---|---|---|---|
| R = Li₂O + Na₂O + K₂O | 19 | 23 | 16.5 | 21.49 |
| a = Li₂O/R | 0.579 | 0.913 | 0.000 | 0.977 |
| b = Na₂O/R | 0.263 | 0.087 | 0.758 | 0.087 |
| C = K₂O/R | 0.158 | 0.000 | 0.242 | 0.005 |
| Q = Al₂O₃/R | 0.632 | 0.217 | 0.485 | 0.209 |
| S = a × b × c | 0.0241 | 0.0000 | 0.0000 | 0.0004 |
| K_{IC} (MPa · m ^{1/2}) | 0.8 | 0.88 | 0.70 | — |
| Young's Modulus (GPa) | 85 | 95 | 75 | 108 |

TABLE 2

| | | | Ex. | Ex. | Ex. | Ex. | Ex. | Ex. | |
|---|---|---|---|---|---|---|---|---|---|
| (Part 1) | | | 1 | 2 | 3 | 4 | 5 | 6 | |
| Glass | Composition | | A | A | A | A | A | A | |
| Material | Thickness | (mm) | 0.55 | 0.55 | 0.55 | 0.55 | 0.55 | 0.55 | |
| | Young's | (GPa) | 85 | 85 | 85 | 85 | 85 | 85 | |
| | Modulus | | | | | | | | |
| | K_{IC} | (MPa · m^{1/2}) | 0.8 | 0.8 | 0.8 | 0.8 | 0.8 | 0.8 | |
| First | First Molten | KNO₃ | 0 | 0 | 0 | 0 | 0 | 0 | |
| Chemical | Salt | NaNO₃ | 100 | 100 | 100 | 100 | 100 | 100 | |
| Strengthening | Composition | LiNO₃ | 0 | 0 | 0 | 0 | 0 | 0 | |
| | (mass %) | | | | | | | | |
| | Temp. | (° C.) | 410 | 410 | 410 | 410 | 410 | 410 | |
| | Time | (min) | 90 | 130 | 150 | 150 | 150 | 150 | |
| Second | Second | KNO₃ | | | | 100 | 100 | 100 | |
| Chemical | Molten Salt | NaNO₃ | — | — | — | 0 | 0 | 0 | |
| Strengthening | Composition | LiNO₃ | — | — | — | 0 | 0 | 0 | |
| | (mass %) | | | | | | | | |
| | Temp. | (° C.) | — | — | — | 440 | 440 | 440 | |
| | Time | (min) | — | — | — | 60 | 120 | 240 | |
| | | | Ex. | Ex. | Ex. | Ex. | Ex. | Ex. | |
| | | | 7 | 8 | 9 | 10 | 11 | 12 | |
| Glass | Composition | | A | A | A | A | A | A | |
| Material | Thickness | (mm) | 0.55 | 0.55 | 0.55 | 0.55 | 0.55 | 0.55 | |
| | Young's | (GPa) | 85 | 85 | 85 | 85 | 85 | 85 | |
| | Modulus | | | | | | | | |
| | K_{IC} | (MPa · m^{1/2}) | 0.8 | 0.8 | 0.8 | 0.8 | 0.8 | 0.8 | |
| First | First Molten | KNO₃ | 0 | 0 | 0 | 0 | 0 | 0 | |
| Chemical | Salt | NaNO₃ | 100 | 100 | 100 | 100 | 100 | 100 | |
| Strengthening | Composition | LiNO₃ | 0 | 0 | 0 | 0 | 0 | 0 | |
| | (mass %) | | | | | | | | |
| | Temp. | (° C.) | 410 | 410 | 410 | 410 | 410 | 410 | |
| | Time | (min) | 150 | 150 | 150 | 150 | 150 | 150 | |
| Second | Second | KNO₃ | 99 | 99 | 99 | 98 | 98 | 98 | |
| Chemical | Molten Salt | NaNO₃ | 1 | 1 | 1 | 2 | 2 | 2 | |
| Strengthening | Composition | LiNO₃ | 0 | 0 | 0 | 0 | 0 | 0 | |
| | (mass %) | | | | | | | | |
| | Temp. | (° C.) | 440 | 440 | 440 | 440 | 440 | 440 | |
| | Time | (min) | 60 | 120 | 240 | 60 | 120 | 240 | |
| | | | Ex. | Ex. | Ex. | Ex. | Ex. | Ex. | Ex. |
| (Part 2) | | | 13 | 14 | 15 | 16 | 17 | 18 | 19 |
| Glass | Composition | | A | B | B | B | B | B | C |
| Material | Thickness | (mm) | 0.7 | 0.55 | 0.55 | 0.55 | 0.55 | 0.7 | 0.55 |
| | Young's | (GPa) | 85 | 95 | 95 | 95 | 95 | 95 | 75 |
| | Modulus | | | | | | | | |
| | K_{IC} | (MPa · m^{1/2}) | 0.8 | 0.88 | 0.88 | 0.88 | 0.88 | 0.88 | 0.7 |
| First | First Molten | KNO₃ | 0 | 0 | 0 | 0 | 0 | 0 | 100 |
| Chemical | Salt | NaNO₃ | 100 | 100 | 99 | 100 | 100 | 100 | 0 |
| Strengthening | Composition | LiNO₃ | 0 | 0 | 1 | 0 | 0 | 0 | 0 |
| | (mass %) | | | | | | | | |
| | Temp. | (° C.) | 410 | 410 | 410 | 410 | 410 | 410 | 410 |
| | Time | (min) | 120 | 90 | 150 | 120 | 120 | 150 | 30 |
| Second | Second | KNO₃ | — | — | — | 100 | 100 | — | — |
| Chemical | Molten Salt | NaNO₃ | — | — | — | 0 | 0 | — | — |
| Strengthening | Composition | LiNO₃ | — | — | — | 0 | 0 | — | — |
| | (mass %) | | | | | | | | |
| | Temp. | (° C.) | — | — | — | 410 | 410 | — | — |
| | Time | (min) | — | — | — | 60 | 240 | — | — |

| | | | Ex. | Ex. | Ex. | Ex. | Ex. | Ex. |
|---|---|---|---|---|---|---|---|---|
| | | | 20 | 21 | 22 | 23 | 24 | 25 |
| Glass | Composition | | C | C | C | C | P | P |
| Material | Thickness | (mm) | 0.55 | 0.55 | 0.55 | 0.7 | 0.55 | 0.55 |
| | Young's | (GPa) | 75 | 75 | 75 | 75 | 108 | 108 |
| | Modulus | | | | | | | |
| | K_{IC} | (MPa · m^{1/2}) | 0.7 | 0.7 | 0.7 | 0.7 | 1.1 | 1.1 |
| First | First Molten | KNO₃ | 100 | 100 | 100 | 100 | 100 | 100 |
| Chemical | Salt | NaNO₃ | 0 | 0 | 0 | 0 | 0 | 0 |
| Strengthening | Composition | LiNO₃ | 0 | 0 | 0 | 0 | 0 | 0 |
| | (mass %) | | | | | | | |
| | Temp. | (° C.) | 410 | 410 | 410 | 410 | 450 | 450 |
| | Time | (min) | 120 | 210 | 270 | 30 | 420 | 420 |
| Second | Second | KNO₃ | — | — | — | — | 100 | 100 |
| Chemical | Molten Salt | NaNO₃ | — | — | — | — | 0 | 0 |
| Strengthening | Composition | LiNO₃ | — | — | — | — | 0 | 0 |
| | (mass %) | | | | | | | |
| | Temp. | (° C.) | — | — | — | — | 420 | 440 |
| | Time | (min) | — | — | — | — | 60 | 60 |

TABLE 3

| | | | Ex. | Ex. | Ex. | Ex. | Ex. | Ex. | |
|---|---|---|---|---|---|---|---|---|---|
| (Part 1) | | | 1 | 2 | 3 | 4 | 5 | 6 | |
| Stress | K_CS₀ | (MPa) | — | — | — | 1120 | 900 | 750 | |
| Profile | K_DOL | (μm) | — | — | — | 7.0 | 10.0 | 12.5 | |
| | CS₀ | (MPa) | 300 | 320 | 310 | 1120 | 900 | 750 | |
| | CS₃₀ | (MPa) | 178 | 183 | 185 | 129 | 75 | 32 | |
| | CS₅₀ | (MPa) | 95 | 100 | 105 | 85 | 44 | 1 | |
| | CS₉₀ | (MPa) | −9 | 4 | 14 | 26 | 9 | −14 | |
| | CS₁₂₀ | (MPa) | −50 | −44 | −38 | −18 | −16 | −23 | |
| | DOL | (μm) | 86 | 92 | 97 | 105 | 101 | 94 | |
| | Na_DOL | (μm) | 86 | 92 | 97 | 105 | 101 | 94 | |
| | CTMax | (MPa) | 75.5 | 86.1 | 94.8 | 88.7 | 91.1 | 63.4 | |
| | CTave | (MPa) | 63 | 69 | 74 | 67 | 54 | 37 | |
| | ICT | (Pa · m) | 24023 | 25376 | 26373 | 26235 | 18792 | 13394 | |
| Calculated | X | | −30.8 | −25.2 | −18.9 | 0.9 | 2.8 | −4.5 | |
| Value | | | | | | | | | |
| Impact Resistance Test (J) | | | N | N | N | N | N | N | |
| 4PB Stress | Average | (MPa) | 100 | 112 | 125 | 152 | 160 | 138 | |
| Evaluation | Fracture | | | | | | | | |
| | Stress | | | | | | | | |
| | | | Ex. | Ex. | Ex. | Ex. | Ex. | Ex. | |
| (Part 1) | | | 7 | 8 | 9 | 10 | 11 | 12 | |
| Stress | K_CS₀ | (MPa) | 896 | 835 | 713 | 860 | 800 | 710 | |
| Profile | K_DOL | (μm) | 7.0 | 9.0 | 11.0 | 7.2 | 9.0 | 13.0 | |
| | CS₀ | (MPa) | 896 | 835 | 713 | 860 | 800 | 710 | |
| | CS₃₀ | (MPa) | 132 | 85 | 43 | 127 | 90 | 49 | |
| | CS₅₀ | (MPa) | 90 | 52 | 11 | 87 | 59 | 19 | |
| | CS₉₀ | (MPa) | 21 | 13 | −9 | 16 | 13 | −2 | |
| | CS₁₂₀ | (MPa) | −19 | −15 | −21 | −17 | −14 | −22 | |
| | DOL | (μm) | 105 | 102 | 98 | 103 | 103 | 97 | |
| | Na_DOL | (μm) | 105 | 102 | 98 | 103 | 103 | 97 | |
| | CTMax | (MPa) | 105.5 | 94.2 | 64.1 | 109.0 | 96.3 | 66.8 | |
| | CTave | (MPa) | 68 | 55 | 35 | 58 | 58 | 40 | |
| | ICT | (Pa · m) | 23120 | 19030 | 12390 | 19952 | 19952 | 14240 | |
| Calculated | X | | 0.3 | 4.2 | −2.1 | 1.9 | 4.8 | −3.1 | |
| Value | | | | | | | | | |
| Impact Resistance Test (J) | | | N | N | N | N | N | N | |
| 4PB Stress | Average | (MPa) | 155 | 163 | 141 | 155 | 160 | 140 | |
| Evaluation | Fracture | | | | | | | | |
| | Stress | | | | | | | | |
| | | | Ex. | Ex. | Ex. | Ex. | Ex. | Ex. | |
| (Part 2) | | | 13 | 14 | 15 | 16 | 17 | 18 | |
| Stress | K_CS₀ | (MPa) | — | — | — | 900 | 800 | — | |
| Profile | K_DOL | (μm) | — | — | — | 2.5 | 3.5 | — | |
| | CS₀ | (MPa) | 280 | 480 | 500 | 900 | 800 | 530 | |
| | CS₃₀ | (MPa) | 202 | 317 | 333 | 248 | 124 | 369 | |
| | CS₅₀ | (MPa) | 120 | 169 | 208 | 186 | 105 | 244 | |
| | CS₉₀ | (MPa) | 22 | −28 | 12 | 41 | 50 | 45 | |
| | CS₁₂₀ | (MPa) | −26 | −91 | −70 | −44 | −3 | −43 | |
| | DOL | (μm) | 102 | 82 | 90 | 103 | 118 | 103 | |
| | Na_DOL | (μm) | 102 | 82 | 90 | 103 | 118 | 103 | |
| | CTMax | (MPa) | 67.8 | 122 | 145 | 141 | 125 | 122 | |
| | CTave | (MPa) | 58 | 105 | 122 | 110 | 84 | 105 | |
| | ICT | (Pa · m) | 22846 | 40567 | 45140 | 37734 | 26261 | 51940 | |
| Calculated | X | | −7.1 | −71.3 | −50.0 | −23.8 | 17.0 | −23.0 | |
| Value | | | | | | | | | |
| Impact Resistance Test (J) | | | N | N | N | N | N | N | |
| 4PB | Average | (MPa) | 138 | 60 | 100 | 138 | 200 | 139 | |
| Stress | Fracture | | | | | | | | |
| Evaluation | Stress | | | | | | | | |
| | | | Ex. | Ex. | Ex. | Ex. | Ex. | Ex. | Ex. |
| (Part 2) | | | 19 | 20 | 21 | 22 | 23 | 24 | 25 |
| Stress | K_CS₀ | (MPa) | 852 | 906 | 905 | 899 | 850 | 900 | 850 |
| Profile | K_DOL | (μm) | 13.0 | 24.0 | 31.0 | 35.0 | 14.0 | 0.6 | 1.0 |
| | CS₀ | (MPa) | 852 | 906 | 905 | 899 | 850 | 900 | 850 |
| | CS₃₀ | (MPa) | −22 | −48 | 29 | 40 | −18 | 125 | 115 |
| | CS₅₀ | (MPa) | −22 | −48 | −66 | −77 | −18 | 60 | 65 |
| | CS₉₀ | (MPa) | −22 | −48 | −66 | −77 | −18 | 0 | 2 |
| | CS₁₂₀ | (MPa) | −22 | −48 | −66 | −77 | −18 | −20 | −33 |
| | DOL | (μm) | 13 | 24 | 31 | 35 | 14 | 90 | 92 |
| | Na_DOL | (μm) | — | — | — | — | — | 90 | 92 |
| | CTMax | (MPa) | 22 | 48 | 66 | 77 | 18 | 80 | 82 |
| | CTave | (MPa) | 21 | 43 | 57 | 66 | 18 | 50 | 52 |
| | ICT | (Pa · m) | 11076 | 21744 | 28055 | 31465 | 11900 | 18500 | 19032 |
| Calculated | X | | −4.5 | −30.1 | −48.1 | −59.0 | −0.7 | 1.3 | −11.7 |
| Value | | | | | | | | | |
| Impact Resistance Test (J) | | | N | N | N | N | N | N | N |
| 4PB | Average | (MPa) | 110 | 70 | 40 | 30 | 117 | 160 | 142 |
| Stress | Fracture | | | | | | | | |
| Evaluation | Stress | | | | | | | | |

From the results shown in Table 3, it was confirmed that the chemically strengthened glass (Ex. 4, 5, 7, 8, 10, 11, 17 and 24), having a surface compressive stress of 600 MPa or greater, a depth of compressive stress layer of 10 to 175 μm and a value of X, expressed by the formula (1), being greater than or equal to 0, exhibited high average fracture stress and consequently high fracture strength.

In contrast, in Ex. 1 to 3, 6, 9, 12 to 16, 18 to 23 and 25 where the value of X was below zero, the fracture stress was low, and consequently, the fracture strength was inferior.

In the above-described impact resistance test, the lifting height of the pendulum 45 was adjusted to vary the impact energy, and the depth of cracks generated in the surface region of the glass sample 43 was observed with an optical microscope. More specifically, a fracture initiation site on the glass surface was first observed with an optical microscope. The fracture initiation site was then removed with tweezers without applying any load, and the thus-exposed fracture surface was observed with the optical microscope. Based on these observations of the fracture surface, the maximum crack depth in the glass sample 43 was determined. The maximum crack depth was plotted as a function of the impact energy. The resulting plot is shown in FIG. 5.

The maximum crack depth was herein determined by observing the fracture surface at the crack initiation site of the glass, drawing a perpendicular line from the outermost surface of the glass to the deepest point of the crack, and measuring the distance between the outermost surface of the glass and the deepest point of the crack along this line. The maximum crack depth refers to the average of the maximum crack depths in five glass samples 43.

As can be seen from FIG. 5, a correlation was observed between the impact energy and the maximum crack depth.

This application is a continuation of PCT Application No. PCT/JP2024/042577, filed on Dec. 2, 2024, which is based upon and claims the benefit of priority from Japanese Patent Application No. 2023-206400 filed on Dec. 6, 2023. The contents of those applications are incorporated herein by reference in their entireties.

### REFERENCE SYMBOLS

41: Stage
42: Block stand
43: Glass sample
44: Sandpaper
45: Pendulum

What is claimed is:

1. A chemically strengthened glass having:
a thickness of 0.6 mm or less;
a surface compressive stress of 600 MPa or greater;
a depth of compressive stress layer of 10 to 175 μm; and
a value of X, expressed by the following formula (1), being greater than or equal to 0:
$$X = 2.05 \times {E}_{m}^{0.5} + {CS}_{120} \qquad ( 1 )$$
where
Eₘ is a Young's modulus at an in-plane center position of the chemically strengthened glass, in units of GPa; and
CS₁₂₀ is a compressive stress at a depth of 120 μm in the chemically strengthened glass, in units of MPa.

2. The chemically strengthened glass according to claim 1, wherein the Young's modulus at the in-plane center position of the chemically strengthened glass is 80 GPa or higher.

3. The chemically strengthened glass according to claim 1, wherein a fracture toughness value K_{IC} at the in-plane center position of the chemically strengthened glass is 0.80 MPa·m^{1/2} or higher.

4. The chemically strengthened glass according to claim 1, wherein no fracture occurs when one surface of the chemically strengthened glass is brought into contact with an abrasive surface of #80 sandpaper comprising silicon carbide as an abrasive, and an impact with an energy of 0.03 J is applied from the side opposite to the abrasive surface of the sandpaper.

5. The chemically strengthened glass according to claim 1, having a composition at a thickness center position thereof, comprising, in mole percentage on an oxide basis:
60 to 72% of SiO₂;
10 to 20% of Al₂O₃;
3 to 12% of Li₂O;
0.5 to 5% of Na₂O;
0 to 3% of K₂O;
0 to 10% of MgO;
0 to 10% of CaO;
0 to 5% of SrO;
0 to 5% of ZnO;
0 to 3% of TiO₂;
0 to 3% of ZrO₂;
0 to 1% of SnO₂,
0 to 1% of P₂O₅;
0 to 10% of B₂O₃; and
0 to 3% of Y₂O₃,
wherein:
a sum R of the contents of Li₂O, Na₂O and K₂O is 5 to 20%,
a ratio of the content of Li₂O to R is 0.5 to 0.95, and
a product of the ratios of the contents of Li₂O, Na₂O and K₂O to R is 0.001 to 0.03.

6. The chemically strengthened glass according to claim 5, wherein a Young's modulus at the thickness center position of the chemically strengthened glass is 85 GPa or higher.

7. The chemically strengthened glass according to claim 1, having a composition at a thickness center position thereof, comprising, in mole percentage on an oxide basis:
55 to 75% of SiO₂;
3 to 18% of Al₂O₃;
17 to 30% of Li₂O;
0 to 3% of Na₂O;
0 to 1% of K₂O;
0 to 10% of MgO;
0 to 10% of CaO;
0 to 5% of SrO;
0 to 5% of ZnO;
0 to 3% of TiO₂;
0 to 3% of ZrO₂;
0 to 1% of SnO₂;
0 to 3% of P₂O₅;
0 to 10% of B₂O₃; and
0 to 3% of Y₂O₃,
wherein:
a sum R of the contents of Li₂O, Na₂O and K₂O is 8 to 35%;
a ratio of the content of Li₂O to R is 0.85 to 0.99; and
a product of the ratios of the contents of Li₂O, Na₂O and K₂O to R is 0 to 0.003.

8. The chemically strengthened glass according to claim 7, wherein a Young's modulus at the thickness center position of the chemically strengthened glass is 90 GPa or higher.

9. A cover glass comprising the chemically strengthened glass according to claim 1.

10. A display comprising the cover glass according to claim 9.

11. A solar cell module comprising the cover glass according to claim 9.
